(19) United States
(12) Patent Application Publication
(10) Pub. No.: US 2025/0209234 A1
(43) Pub. Date: Jun. 26, 2025

(54) ELECTRICAL GRID SERVICE MONITORING, VALUATION, AND CONTROL

(71) Applicant: X Development LLC, Mountain View, CA (US)

(72) Inventors: Leo Francis Casey, San Francisco, CA (US); Page Furey Crahan, San Francisco, CA (US); Laura Elizabeth Fedoruk, Burlingame, CA (US); Patrick Raab, San Francisco, CA (US); Hamed Khalilinia, San Mateo, CA (US); Andrew Lee Ott, Pottstown, PA (US); Raymond Daly, Palo Alto, CA (US); Sze Mei Cat Wong, Johns Creek, GA (US)

(21) Appl. No.: 18/394,120

(22) Filed: Dec. 22, 2023

(51) Int. Cl. G06F 30/20

(52) U.S. Cl. CPC G06F 30/20

(57) ABSTRACT

A method for electrical grid service monitoring and valuation includes detecting a connection of a grid asset to an electric grid; receiving, from the grid asset, a communication indicating operating parameters for the grid asset; adding, to a database of grid assets, an identifier for the grid asset and the operating parameters; and simulating conditions of the electric grid based on data corresponding to a plurality of grid assets, the data being stored in the database; obtaining data indicating a status of the grid asset; determining that the grid asset is performing a grid service; obtaining an estimated value of the grid service using simulation results; obtaining energy market data indicating a market value of energy provided by the electric grid; and determining a value for the grid service performed based on (a) the estimated value of the grid service and (b) the energy market data.

### TECHNICAL FIELD

This specification relates generally to electrical distribution system monitoring systems.

### BACKGROUND

Electrical distribution systems transmit electrical power to loads such as residential and commercial buildings through electrical power lines. Most electrical distribution systems are either unmonitored or monitored only by a power substation.

### SUMMARY

In general, the disclosure relates to systems and methods for electrical grid service monitoring, valuation, and control. The disclosed techniques can be executed as a platform architecture that executes a framework for sustaining grid stability. The technology is related to determining values for grid services provided by grid assets such as distributed electrical resources (DERs) (e.g., generators, solar panels, electrical vehicles). The value of grid services performed by grid assets can be determined based on a combination of simulations and real time sensor data. The value of grid services can be computed based on factors such as a location of an asset on the grid, time, and type of energy source. The disclosed system can track grid assets that share power with the grid, and evaluate the impact of the grid assets based on a local marginal value of the electric grid services provided.

The present disclosure provides processes for verifying availability of DERs on an electric grid and enabling compensation for account owners for maintaining availability of the DERs. The processes for verifying availability of DERs and determining compensation for account owners can be centralized, such as a central power grid system routinely pinging each DER to verify and record the availability of the DER. In some examples, the processes can be executed through a distributed network where individual DERs verify availability of each other. Availability can be recorded on a distributed network, with transactions being issued for each positive verification.

When a fault or other electric grid event occurs, the disclosed techniques can be used to identify which DER(s) reacted autonomously to ensure the stability of the grid during the event. The availability verification data for the DERs can be used as a first order filter for the identification of the DER(s) that reacted autonomously. Once identified, the value of each DER's response can be computed based on the type of grid event that occurred, the type of stability service provided by the DER (e.g., regulating voltage, absorbing excess reactive power, regulating frequency, etc.) and the electrical location of the DER on the grid. The disclosed techniques can be used to identify future or current demand for grid services, and to assign performance of the grid services to individual DERs.

The disclosed techniques can be used to compute the value of different types of grid stability services that DERs might provide at different locations on the grid. First order value can be calculated based on simulations of the grid and of expected loads and demands at different locations, and based on the potential effect of different types of destabilization to the grid. Second order value can be determined during and/or after an event occurs based on the value of the individual DERs reacting to stabilize the grid.

The methods and systems presented herein provide at least the following technical advantages and/or technical improvements over previously available solutions. The techniques can be used to determine the value of grid services using real-time or near real-time electric grid data. The monitoring platform can identify demands on the electric grid, including types and locations of demands. The platform can identify available DERs, assign DERs to perform services to stabilize the electric grid, monitor performance of the DERs during performance of the grid services, and compute the value of the services. The disclosed techniques use simulations to predict electric grid demand and to predict service value, to enable rapid and accurate response and valuation when an electric grid event occurs. The disclosed techniques can be used to identify times and locations of demand for grid services, and to verify and ensure availability of DERs, in order to improve grid stability, electrical power quality, and safety.

Methods in accordance with the present disclosure may include any combination of the aspects and features described herein. That is, methods in accordance with the present disclosure are not limited to the combinations of aspects and features specifically described herein, but also include any combination of the aspects and features provided.

The details of one or more implementations of the present disclosure are set forth in the accompanying drawings and the description below. Other features and advantages of the present disclosure will be apparent from the description and drawings, and from the claims.

### BRIEF DESCRIPTION OF THE DRAWINGS

FIG. 1 is a diagram of an example system for electrical grid monitoring and grid service valuation.

FIG. 2 illustrates example communications within an example system for electrical grid monitoring and grid service valuation under a first set of operating conditions.

FIG. 3 illustrates example communications within an example system for electrical grid monitoring and grid service valuation at a second set of operating conditions.

FIG. 4 is a diagram of an example grid monitoring server.

FIG. 5 is a diagram of a system for training a grid simulation model.

FIG. 6 is a diagram of a system for training a service value estimation model.

FIG. 7 is a flowchart of an example process for creating a database of assets for providing grid services.

FIG. 8 is a flowchart of an example process for estimating the value of grid services based on simulation results.

FIG. 9 is a flowchart of an example process for determining the value of a grid service performed by a grid asset.

FIG. 10 is a flowchart of an example process for assigning grid assets to perform grid services.

Like reference numbers and designations in the various drawings indicate like elements.

### DETAILED DESCRIPTION

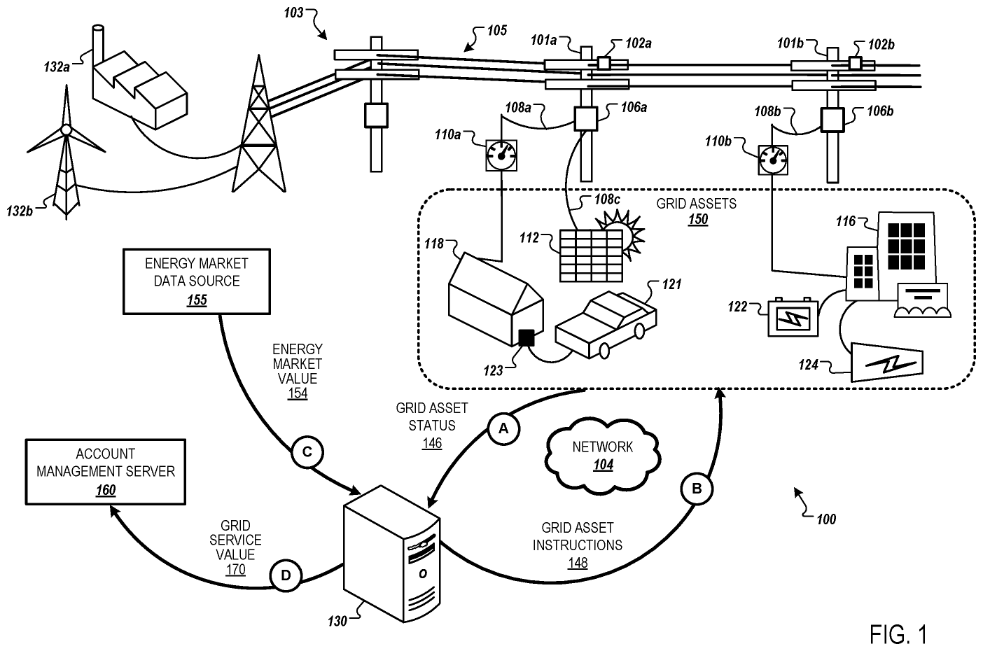

FIG. 1 is an example system 100 for electrical grid monitoring and grid service valuation. The system 100 includes utility poles 101a, 101b (“utility poles 101”) that support three-phase primary distribution lines 105 of an electrical distribution system, or electric grid 103. The primary distribution lines 105 transport electrical power from power generation systems of the electric grid 103 to electrical loads of the electric grid 103. The power generation systems can include, for example, power plants 132a, 132b. The power plant 132a can be, for example, a nuclear power plant or a conventional power plant. The power plant 132b is a wind power plant. Other power generation systems can include, but are not limited to, photovoltaic power plants, biomass and biogas power plants, geothermal power plants, and hydropower plants. Electric generating power plants, such as power plants 132a, 132b, commonly produce three-phase alternating current (AC) electrical power. The voltage of electric power can be increased or reduced by electrical transformers located between power plants and loads. On one side of an electrical transformer, the transformer can be connected to a primary electrical distribution system that is connected to a power source. On another side of the electrical transformer, the transformer can be connected to a secondary distribution system that distributes the power to loads. In the system 100, the utility poles 101 each support a distribution transformer 106a, 106b (“transformers 106”) respectively. The distribution transformers 106 step down the voltage of the electrical power from the primary distribution lines 105 to one or more secondary distribution lines. In some examples, a single transformer connects to a single phase of the primary distribution lines 105.

Although shown in FIG. 1 as supporting a single transformer, in some examples, a single utility pole supports more than one transformer, e.g., two or three transformers. In some examples, each transformer supported by a utility pole connects to a different phase of the primary distribution lines. For example, a utility pole can have a first transformer connected to the “A” phase of the primary distribution lines 105, a second transformer connected to the “B” phase of the primary distribution lines 105, and a third transformer connected to the “C” phase of the primary distribution lines 105.

The power generated by the power plants 132a, 132b can be distributed through power lines of an electrical grid, such as distribution lines 105, to service cables that connect electrical loads, such as residential, commercial, and industrial properties, to the electrical grid. An example load is a house 118. As depicted in FIG. 1, the house 118 receives electrical power from a secondary distribution line 108a connected to the transformer 106a. Another example load is an office building 116. The office building 116 receives electrical power from a secondary distribution line 108b connected to the transformer 106b.

Meters, panels, or other electrical monitoring devices can be connected to a service cable at a load, such as a residential property, in order to monitor electricity usage of the load. Data collected by the meters can include, for example, voltage, current, power factor, and the amount of energy consumed by the electrical load. For example, a meter 110a measures characteristics of power flowing from the secondary distribution line 108a to the house 118. A meter 110b measures characteristics of power flowing from the secondary distribution line 108b to the office building 116. Meters 110a, 110b (“meters 110”) can have communication capabilities that allow the meter 110 to communicate information to the consumer and to electricity suppliers for system monitoring and billing. The meters 110 can communicate through wired communications, wireless communications, or both.

The system 100 includes sensors 102a, 102b (“sensors 102”) that can be used to measure a wide variety of physical parameters in power generation, transmission lines, substations, distribution lines, energy storage, and customers. These include current transformers (CTs), voltage transformers (VTs), phasor measurement units (PMUs), merging units (MUs), smart meters, temperature sensors, humidity sensors, accelerometers, rain gauges, internet protocol (IP) network cameras, pyranometers and pyrheliometers (solar irradiance), weather stations, sonic anemometers, partial discharge sensors, gas sensors, ultrasound and ultra-high frequency sensors, torque sensors, discharge rate sensors, load leveling sensors, occupancy sensors, and power quality monitors. In some examples, the sensors 102 can include voltage sensors, current sensors, and frequency sensors. The sensors 102 can include line sensors with Remote Terminal Units (RTUs).

In some examples, a sensor 102 is a phasor measurement unit (PMU)-based smart sensor. A PMU is a device that produces synchronized phasor, frequency, and rate of change of frequency (ROCOF) estimates from input voltage and/or current signals together with a time synchronizing reference signal. PMUs provide real-time synchrophasor data for advanced applications, such as wide-area situational awareness, state estimation, monitoring system dynamics, and validating system models. In some examples, a sensor is a merging unit (MU)-based smart sensor. An MU samples AC signals in one or multiple phases, converts analog voltage and current signals to digital values, merges multiple phases together based on time synchronization, and transmits sampled values to protection relays through networks (e.g., based on the International Electrotechnical Commission (IEC) 61850-9-2 standard protocol). MUs provide real-time status of power grids.

The system 100 includes grid assets 150. A grid asset is a component that is connectable to the electric grid 103 and can function as an electrical load, an electrical source, or both. A grid asset can be, for example, a distributed energy resource (DER), an inverter-connected resource, an appliance, an electrical power supply, an electric vehicle, an energy storage resource, or any combination thereof. Distributed energy resources (DERs) are small-scale energy resources that are usually situated near sites of electricity use, such as rooftop solar panels and battery storage. DERs can provide valuable services to the grid and can be used to improve system reliability and reduce overall energy costs.

The grid assets 150 of the system 100 include an electric vehicle 121, a photovoltaic (PV) power supply 112, a battery 122, and a generator 124. The PV power supply 112 is connected to the transformer 106a by distribution line 108c. The electric vehicle 121 is connectable to the electric grid 103 through a charging station 123 installed at the house 118. In some examples, the electric vehicle 121 is connectable to the electric grid 103 at an alternative location, such as a workplace (e.g., office building 116). The battery 122 and the generator 124 are connectable to the electric grid 103 through the office building 116. The battery 122 and the generator 124 may be backup power supplies for electrical loads within the office building 116.

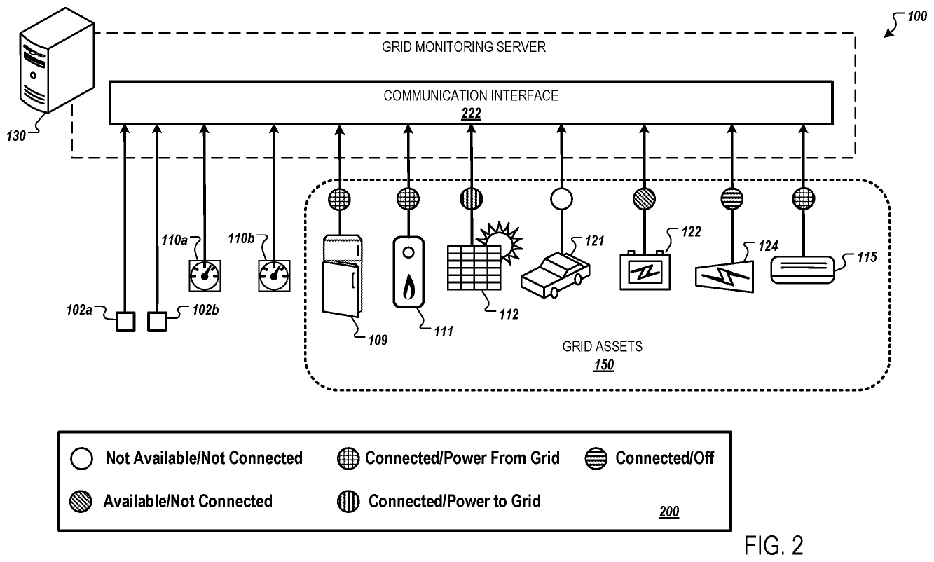

The house 118 and the office building 116 can contain other grid assets. For example, referring to FIG. 2, which illustrates example communications within the system 100, the house 118 contains a refrigerator 109 and a water heater 111, and the office building 116 contains an air conditioner 115.

In some examples, a grid asset is capable of generating data representing characteristics, operating parameters, and statuses of the grid asset. The data can include, for example, voltage, current, power factor, and the amount of energy consumed by or provided by the grid asset. For example, the electric vehicle 121 can generate data representing a charging status of the electric vehicle 121, a charge level of a battery of the vehicle 121, a connection location of the vehicle 121 to the electric grid 103, a status of a connection of the vehicle 121 to the electric grid 103, or any combination thereof. Similarly, the PV power supply 112 can generate data representing an amount of power generated by the PV power supply 112, a status of a connection of the PV power supply 112 to the electric grid 103, or both.

In some examples, grid assets 150, sensors 102, and meters 110 are capable of communication with other components of the electric grid 103, such as the grid monitoring server 130. The electrical distribution system, including the grid assets 150, can form an internet-of-things (IoT) network. For example, grid assets can have communication capabilities that allow the grid asset to communicate information wirelessly or over a fixed communication network to the consumer and to electricity suppliers for system monitoring and billing. In some examples, the grid assets can be configured to wirelessly communicate. For example, the grid assets can be configured to communicate through cellular communications, Bluetooth communications, WiFi communications, a mesh network, etc. In some examples, the grid assets can be configured to communicate through a fixed, e.g., wired, communication network. In some examples, the grid assets can communicate over the distribution lines 105. For example, the grid assets can communicate using a high frequency carrier signal transmitted over the distribution lines 105 or along the distribution lines 105. In some examples, data from the grid assets can include time stamps that are referenced to accurate time references, e.g., a GPS time base or network time. The data from the grid assets can include timestamps indicating the time when the data was collected. In some examples, time synchronization is provided by GPS or IEEE 1588 Precision Time Protocol, which allows synchronized real-time measurements of multiple remote points on the electric grid 103.

The grid monitoring server 130 can be a computer server or group of computer servers maintained by an electrical utility or service provider. The grid monitoring server 130 can include a communications interface for communicating with grid assets. The grid monitoring server 130 can communicate with the grid assets 150 over a network 104 using, for example, a long-range wired or wireless connection. The network 104 can be a long range communication network and can include the internet. The grid monitoring server 130 may connect via Wi-Fi, Bluetooth, or any other protocol used to communicate with grid assets 150.

The grid monitoring server 130 can communicate with other servers and systems. For example, the grid monitoring server 130 can communicate with an energy market data source 155 and an account management server 160. The energy market data source 155 monitors energy market values in real-time or near real-time. The account management server 160 manages accounts of electric grid customers.

FIG. 1 illustrates various events, shown as stages (A) to (D), each representing a stage of electric grid service monitoring and valuation. Stages (A) to (D) may occur in the illustrated sequence, or in a sequence that is different from the illustrated sequence. For example, some of the stages may occur concurrently.

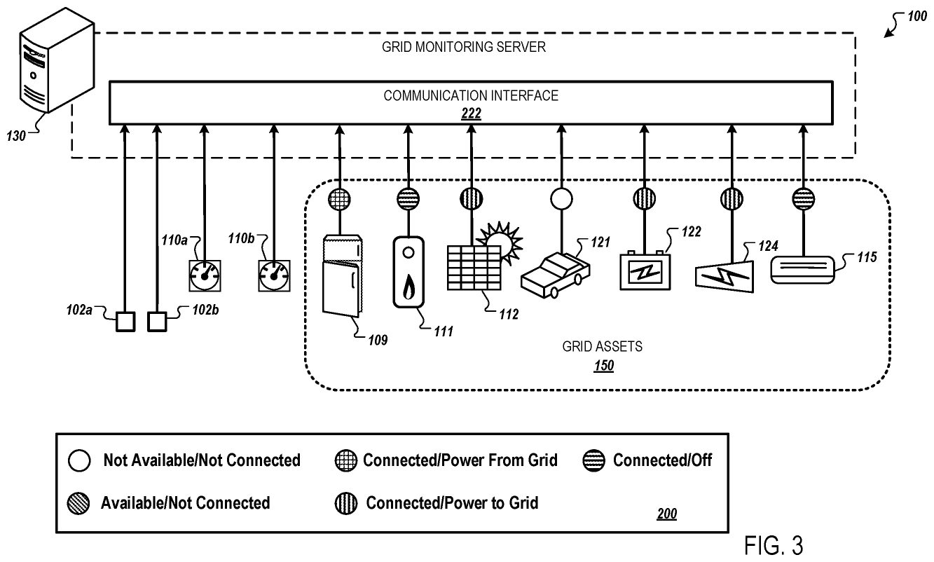

In stage (A), grid assets 150 each provide a grid asset status 146 to the grid monitoring server 130. The grid asset status 146 can include, for example, an electrical load drawn by the grid asset from the electric grid 103, an electrical power provided by the grid asset to the electric grid 103, an on/off status of the grid asset, a power setting of the grid asset, a standby status of the grid asset, a status of the connection of the grid asset to the electric grid 103, or any combination of these statuses. Example communications between the grid assets 150 and the grid monitoring server 130 are shown in FIGS. 2 and 3.

FIG. 2 illustrates example communications within the system 100 with the grid assets 150 operating under a first set of operating conditions, and FIG. 3 illustrates example communications within the system 100 with the grid assets 150 operating under a second set of operating conditions. FIGS. 2 and 3 each include a legend 200 showing representations of different statuses of grid assets 150.

Referring to FIGS. 2 and 3, grid assets 150 of the system 100 communicate with a communication interface 222 of the grid monitoring server 130. Referring to FIG. 2, the grid assets 150 each provide status information to the grid monitoring server 130 while the grid assets 150 are operating under a first set of operating conditions. The first set of operating conditions can be, for example, a set of operating conditions of the electric grid 103 that exist prior to an electric grid event such as a grid fault (e.g., normal or standard operating conditions). When operating under the first set of operating conditions, the refrigerator 109 provides status information to the grid monitoring server 130 indicating that the refrigerator 109 is connected to, and receiving power from, the electric grid 103. When operating under the first set of operating conditions, the water heater 111 provides status information to the grid monitoring server 130 indicating that the water heater 111 is connected to, and receiving power from, the electric grid 103. When operating under the first set of operating conditions, the PV power supply 112 provides status information to the grid monitoring server 130 indicating that the PV power supply is connected to, and providing power to, the electric grid 103. When operating under the first set of operating conditions, the electric vehicle 121 provides status information to the grid monitoring server 130 indicating that the electric vehicle 121 is not available and disconnected from the electric grid 103. In some examples, the grid monitoring server 130 can determine that a grid asset is disconnected from the electric grid 103 based on failing to receive any communication from the grid asset. When operating under the first set of operating conditions, the battery 122 provides status information to the grid monitoring server 130 indicating that the battery 122 is available, but not connected to, the electric grid 103. For example, the battery 122 may be in a standby status in which a switch between the battery 122 and the electric grid 103 is open, or off. When operating under the first set of operating conditions, the generator 124 provides status information to the grid monitoring server 130 indicating that the generator 124 is connected to the electric grid 103, but is powered off. When operating under the first set of operating conditions, the air conditioner 115 provides status information to the grid monitoring server 130 indicating that the air conditioner 115 is connected to, and receiving power from, the electric grid 103.

In some examples, instead of communicating directly with a grid asset 150, the communication interface 222 can communicate with a device configured to monitor a grid asset. For example, an appliance meter or appliance monitor can be configured to monitor a status of the water heater 111, and can communicate the status of the water heater 111 to the communication interface 222. The appliance meter can be similar to the meters 110, except that the appliance meter can be configured to monitor one or several appliances, while the meters 110 monitor all loads on the respective secondary distribution lines 108. In some examples, the communication interface 222 can communicate with a charging station or outlet. For example, the electric vehicle 121 is connectable to the electric grid 103 through the charging station 123. The charging station 123 can include sensors for detecting the status of the electric vehicle 121 (e.g., whether the vehicle is plugged in or not plugged in, a rate of charging of the vehicle, a battery level of the vehicle). The charging station 123 can include a communication interface for communicating the status of the electric vehicle 121 with the communication interface 222 of the grid monitoring server 130.

In some examples, grid assets 150 can provide a grid asset status 146 to the grid monitoring server 130 continuously. In some examples, grid assets 150 can provide a grid asset status 146 to the grid monitoring server 130 intermittently or at designated time intervals. In some examples, the grid assets 150 can provide a grid asset status 146 to the grid monitoring server 130 based on a schedule. In some examples, the grid assets 150 can provide a grid asset status 146 to the grid monitoring server 130 in response to a change in grid asset status occurring.

In some examples, the grid monitoring server 130 sequentially polls the grid assets 150 for a grid asset status 146. For example, the grid monitoring server 130 can send a polling signal to a first grid asset 150. In response to receiving the polling signal, the first grid asset 150 can transmit the grid asset status 146 of the respective grid asset 150 to the grid monitoring server 130. After receiving the grid asset status 146 from the first grid asset 150, the grid monitoring server 130 can then poll the next grid asset 150 in sequence. In this way, the grid monitoring server 130 can repeatedly, continually, or continuously verify availability of the grid assets 150. By sequentially polling the grid assets 150, the amount of data transferred simultaneously can be reduced, improving communications efficiency.

In some examples, grid assets provide a grid asset status 146 to the grid monitoring server 130 in response to an occurrence of an event affecting the electric grid 103. In some examples, the grid monitoring server 130 sends a request for an updated grid assets status 146 to all of the grid assets 150 in response to the grid monitoring server 130 detecting an electric grid event, such as a loss of power. In some examples, the grid monitoring server 130 sends a request for an updated grid assets status 146 to a subset of the grid assets 150 in response to the grid monitoring server 130 detecting an electric grid event. For example, the grid monitoring server 130 can detect an electric grid event, determine a type and/or location of the event, identify a subset of grid assets that are relevant to the event based on the type and/or the location of the event, and send the request to the subset of grid assets 150 identified as relevant to the event.

An electric grid event can be, for example, a load imbalance, an overload condition, an over-voltage or under-voltage condition, an over-current or under-current condition, an over-frequency or under-frequency condition, current surge, voltage collapse, power flow reversal, a power outage, or a signal received from a grid operator. An electric grid event can be, for example, a grid fault. A grid fault is a physical condition that causes a circuit element to fail to perform in the required manner. Grid faults can include short circuits, open circuits, failed devices and overloads. A short circuit is some form of abnormal connection that causes current to flow in some path other than the one intended for proper circuit operation, or of a different magnitude than the normal current. Short circuit faults may have very low impedance (e.g., bolted faults) or may have some significant amount of fault impedance. Bolted faults may result in the operation of a protective device, yielding an outage to some utility customers. Faults that have enough impedance to prevent a protective device from operating can be considered high impedance faults. Such high impedance faults might not result in outages, but can cause power quality issues, and can result in utility equipment damage. Grid faults can include open phase faults, where a conductor has become disconnected, but does not create a short circuit. Open phase faults can be the result of a conductor failure resulting in disconnection, or can be the side effect of a bolted phase fault, where a lateral phase fuse has blown, leaving that phase effectively disconnected. Such open phase faults can result in loss of service to customers and can also result in safety hazards. Any fault may change into another fault type through physical instability or through the effects of arcing, wire burndown, and electromagnetic forces. Such faults are called evolving faults. Bolted faults can be classified as momentary or sustained. High impedance faults can be classified as intermittent (e.g., happening on a recurring basis but not frequently) or persistent (e.g., happening at random but constantly occurring).

Referring to FIGS. 2 and 3, meters 110 and sensors 102 can also communicate with the communication interface 222 of the grid monitoring server 130. For example, the meters 110 can transmit measurement data representing electrical measurements of loads and sources connected to the electric grid 103. The sensors 102 can transmit sensor data representing electrical characteristics of the electric grid 103 at various locations of the electric grid 103.

Referring back to FIG. 1, in stage (B), in response to receiving a grid asset status 146 for one or more of the grid assets 150, the grid monitoring server 130 sends grid asset instructions 148 to the grid assets 150 that cause some or all of the grid assets 150 to perform a grid service. The grid asset instructions 148 can include, for example, an instruction that causes a grid asset to connect to the electric grid 103, an instruction that causes a grid asset to disconnect from the electric grid 103, an instruction that causes the grid asset to power off, an instruction that causes the grid asset to power on, an instruction that causes the grid asset to change power setting, or any combination of these instructions. In some examples, the grid monitoring server 130 sends the grid asset instructions 148 to provide one or more grid services in response to a detected electric grid event and based on the grid asset status 146.

Grid services can be, for example, electrical energy storage, load shifting, fast balancing, peak shaving, frequency regulation, frequency response, voltage regulation, reactive power injection; reactive power absorption, active power injection; emergency energy supply, and inertial service.

Load shifting is an electricity management technique that shifts load demand from peak hours of the day to off-peak hours of the day. For example, load shifting can include causing power storage systems, such as batteries, to be charged during off-peak hours (e.g., at night), instead of during peak hours (e.g., during the day). Similarly, peak shaving is a strategy for avoiding peak demand charges in the electrical grid by quickly reducing power consumption during intervals of high demand. Peak shaving can be performed, for example, by periodically turning off the air conditioner 115 during high demand intervals, or delaying the on-time of other thermal loads such as freezers.

Fast balancing, which can also be referred to as frequency response, ensures the balance of electricity supply and demand at all times, including over time frames from seconds to minutes. Fast balancing is an automatic change in active power output in response to a frequency change, and is used to maintain the frequency within statutory and operational limits. For example, with fast balancing, when supply exceeds demand, the electric grid frequency automatically increases, and when demand exceeds supply, the electric grid frequency automatically decreases. Fast balancing refers to the ability of the bulk power system to autonomously adjust to sudden deviations from the regular AC frequency (e.g., 60 Hertz). Fast balancing is effectively the power system's real-time ability to nearly instantaneously balance electrical supply-demand imbalances, and is a crucial component of essential reliability services. Batteries can be used to perform fast balancing, as batteries are capable of both outputting energy and storing energy. Batteries are fast responding and do not lose efficiency by needing to reserve headroom. Additionally, inverter-based assets such as wind, solar, and storage assets can use power electronics to detect frequency deviations and quickly respond to system imbalances. Tapping into electronic-based resources for fast frequency response can enable response rates many times faster than traditional mechanical response.

Inertial services can maintain grid frequency when a power source is lost. Grid frequency, which is a measure of the balance of supply of electricity and demand, can drop if a large power plant, distribution line, or transformer fails. Inertia is the tendency of an object in motion to remain in motion, and inertia from rotating electrical generators in fossil, nuclear, and hydroelectric power plants represents a source of stored energy that can be tapped for a few seconds to provide the grid time to respond to power plant or other system failures. Stored energy is extracted from the inertia of the spinning generators and can temporarily make up for lost supply of electricity when a power source is lost. Although the rotation of the generators might not be sustained for more than a few seconds, the energy provided by the inertia of these rotational generators provides time for mechanical systems in the grid to detect the imbalance (as reflected in declining frequency) and instruct power plant systems to speed up or slow down energy production.

Voltage regulation is also a critical grid service that can be provided by grid assets 150. Unlike frequency, which is the same throughout the system, voltage varies across the grid. At each point along the electric grid 103, voltage must also be maintained and regulated within acceptable values. Each point along the grid has a desired voltage and a maximum and minimum allowed voltage. An example of acceptable tolerance is five percent from the scheduled voltage. On the transmission system, greater variances are sometimes acceptable. If voltage is too high, protective breakers will open to prevent damage to equipment, causing portions of the grid to lose power. Alternatively, if voltage is too low, distribution utilities may be unable to maintain voltage to their customers, and customer equipment will not operate properly and/or lines will drop off-line causing outages. Voltage can change along a transmission or distribution line based on uncontrollable factors including impedance of the line, line loading, and reactive power consumption by consumers connected to the line. Typically, voltage drops are based on distance from a substation or other source of power. Line voltage may be controlled through the use of transformers and devices that inject or absorb reactive energy. For example, voltage can be managed using various sources of reactive power including capacitors, static VAR compensators (SVC), and synchronous condensors. VAR compensators and synchronous condensors can be continuously adjusted, while capacitors are controlled by being switched in or switched out, either manually or automatically. Generation sources can often be managed to produce more or less reactive power in order to regulate voltage. DERs connected to the electric grid 103 may change the expected voltage profile by injecting current at locations that would otherwise only consume electricity. In some cases, DERs can assist in voltage regulation by providing control of reactive power output through smart inverters. An additional important factor associated with DERs is how DERs behave during temporary drops in voltage. In some examples, DERs include low-voltage ride-through capability so that DERs stay online during short voltage incursions. This can reduce the likelihood of additional system issues caused by DERs suddenly going offline.

In some examples, grid assets can perform multiple different grid services. For example, electric resistance water heaters have heating elements in their tanks that can be fast-controlled at very frequent intervals to accommodate diverse grid needs such as fast balancing services, known as frequency regulation. The water heater 111 can provide a wide range of grid services from fast balancing and peak shaving to load shifting.

In one example, the grid monitoring server 130 can detect an electric grid event including an overload condition. In response, the grid monitoring server 130 can send grid asset instructions 148 to the grid assets 150. In some examples, the grid asset instructions 148 can include instructions that cause the grid assets 150 to change status in order to perform a grid service. For example, an instruction can cause a grid asset to change from an off status to an on status. In some examples, the grid asset instructions 148 can include instructions that cause the grid assets 150 to remain in a current status in order to perform a grid service. For example, an instruction can cause a grid asset to remain in an off status. For example, at the time of the detected overload condition, the air conditioner 115 may be powered off, and configured to switch to an on status when a thermostat rises to a threshold temperature. In response to detecting the overload condition, the grid monitoring server can provide grid asset instructions 148 that cause the air conditioner 115 to remain off, even when the thermostat rises to the threshold temperature.

In the example of FIGS. 2 and 3, the grid asset instructions 148 include an instruction that causes the water heater 111, battery 122, generator 124, and air conditioner 115 to change status in order to provide grid services to the electric grid 103. Specifically, in response to detecting an electric grid event, the grid monitoring server 130 transmits grid asset instructions 148 including an instruction that causes the water heater 111 to power off, an instruction that causes the battery 122 to connect to the electric grid 103 and provide power to the electric grid 103, an instruction that causes generator 124 to connect to the electric grid 103 and provide power to the electric grid 103, and an instruction that causes the air conditioner 115 to power off, as depicted in FIG. 3.

Referring to FIG. 3, the grid assets 150 provide status information to the grid monitoring server 130 at the second set of operating conditions. The second set of operating conditions can be, for example, a set of operating conditions of the electric grid 103 that exist during or after an electric grid event, such as a grid fault, and following receipt of instructions 148 transmitted from the grid monitoring server 130 in response to detecting the electric grid event. In some examples, the grid assets 150 provide the status information to the grid monitoring server 130 in response to a change in the status of the respective grid asset. For example, the grid asset instructions can include an instruction that causes the water heater 111 to power off. In response to receiving the instruction, the water heater 111 can change its power status to off, and then send status information to the grid monitoring server 130 indicating that the water heater 111 is off. In the example depicted in FIG. 3, the refrigerator 109 provides status information to the grid monitoring server 130 indicating that the refrigerator 109 is connected to, and receiving power from, the electric grid 103, the water heater 111 provides status information to the grid monitoring server 130 indicating that the water heater 111 is connected to the electric grid 103, but is powered off, the PV power supply 112 provides status information to the grid monitoring server 130 indicating that the PV power supply is connected to, and providing power to, the electric grid 103, the electric vehicle 121 or the charging station 123 provides status information to the grid monitoring server 130 indicating that the electric vehicle 121 is not available and disconnected from the electric grid 103, the battery 122 provides status information to the grid monitoring server 130 indicating that the battery 122 is connected to, and providing power to, the electric grid 103, the generator 124 provides status information to the grid monitoring server 130 indicating that the generator 124 is connected to, and providing power to, the electric grid 103, and the air conditioner 115 provides status information to the grid monitoring server 130 indicating that the air conditioner 115 is connected to the electric grid 103, but is powered off.

Referring back to FIG. 1, in stage (C), the grid monitoring server 130 obtains energy market value data 154 from the energy market data source 155. The energy market value data 154 can indicate the value of energy grid services being provided by the electric grid 103 in real time or near-real time. The energy market value data 154 corresponds to a type of the electric grid event that occurred and the type of grid service provided.

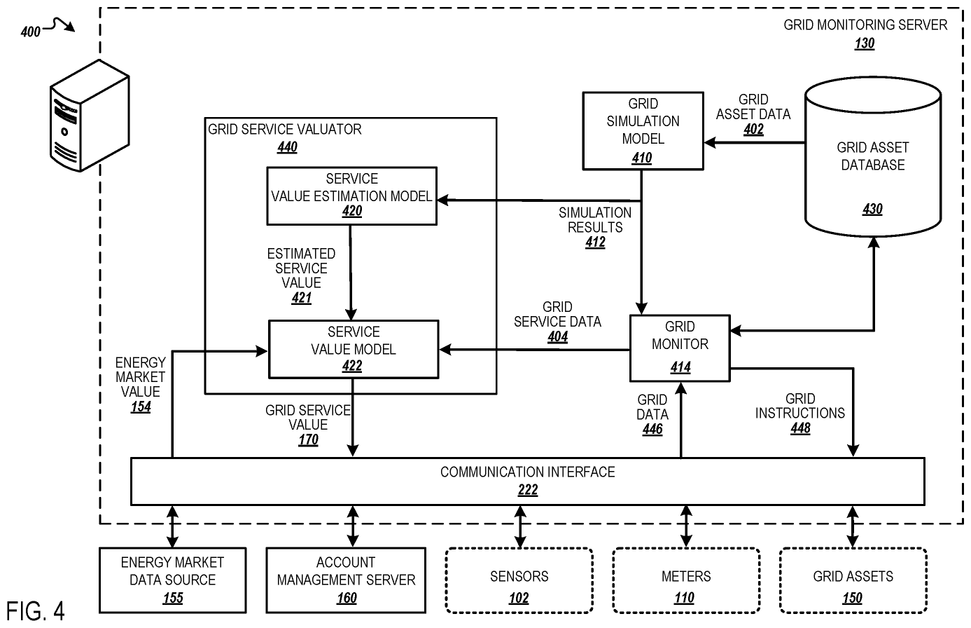

In stage (D), the grid monitoring server 130 generates a grid service value 170 and transmits the grid service value 170 to the account management server 160. The grid service value 170 can be, for example, a value of currency per time increment a particular grid service is provided, a total value of currency for performance of the grid service, an energy credit per time increment the grid service is provided, a total energy credit for performance of the grid service, a time-varying value over a duration of performance of the grid service, or any combination of these values. The grid monitoring server 130 can determine the grid service value 170 based on simulations of electrical conditions of the electric grid 103, based on the grid asset status data 146, based on the energy market value 154, or any combination thereof. Determinations of the grid service value 170 are described in greater detail with reference to FIG. 4.

FIG. 4 is a diagram of an example grid monitoring server 130 for generating grid instructions and determining a grid service value. Components of the grid monitoring server 130 can be provided as one or more computer executable software modules or hardware modules. That is, some or all of the functions of components of grid monitoring server 130 can be provided as a block of computer code, which upon execution by a processor, causes the processor to perform functions described below. Some or all of the functions of components of the grid monitoring server 130 can be implemented in electronic circuitry, e.g., by individual computer systems (e.g., servers), processors, microcontrollers, a field programmable gate array (FPGA), or an application specific integrated circuit (ASIC). As depicted in FIG. 4, the grid monitoring server 130 includes the communication interface 222, a grid service valuator 440, a grid asset database 430, a grid simulation model 410, and a grid monitor 414. The grid service valuator 440 includes a service value estimation model 420, and a service value model 422. The communication interface 222 enables the grid monitoring server 130 to communicate with the grid assets 150, the meters 110, the sensors 102, the account management server 160, and the energy market data source 155.

The grid asset database 430 is a database configured to store information related to grid assets that are connected to and/or connectable to the electric grid 103. The grid asset database 430 can store data related to characteristics and operating parameters, or specifications, of assets of the electrical distribution system. For example, the grid asset database 430 can store data indicating operating parameters of each of the grid assets 150. The grid asset database 430 can also store an identifier for each grid asset 150 and data indicating a location of each grid asset 150. The location of a grid asset can be, for example, a geographical location, a geospatial location, a location of the grid asset relative to the electric grid 103, or any combination of these locations. In some examples, the location of a grid asset includes an identification of a transformer and/or a feeder to which the grid asset is connected or connectable. In the grid asset database 430, each grid asset 150 can be identified by a unique identifier. A database entry for a grid asset can include any combination of the following information related to the grid asset: the identifier, a type of the asset, a location, operating parameters, an availability status, a time of the most recent status update. In some examples, an entry for a grid asset can include a list of grid services that the grid asset is capable of performing, a list of services that the grid asset is committed or contracted to perform, a list of grid conditions that are expected to cause autonomous activation of the grid asset, or any combination of these features. For example, an example database entry for the generator 124 can include identifier: “GEN456”; asset type: natural gas generator; location: office building 116/transformer 106b; activation mode: automatic; status: standby; timestamp for status update: Feb. 25, 2025, 10:03:01 am. The database entry for the generator 124 can also include operating parameters of, for example, rated watts: 21 kilowatts; rated amps: 100 amps; voltage: 120/240 volts; frequency: 60 Hz. As another example, an example database entry for the electric vehicle 121 can include identifier: “VEH789”; asset type: electric vehicle; location: house 118/transformer 106a; activation mode: on command; status: connected, charging; timestamp for status update: Feb. 25, 2025, 10:15:04 am. The database entry for the electric vehicle 121 can also include operating parameters of, for example, battery capacity: 100 kWh; voltage: 800 volts.

In some examples, the grid asset database 430 can be updated in response to grid assets connecting to and disconnecting from the electric grid 103. For example, the grid monitoring server 130 can detect, based on communications with sensors 102, meters 110, and grid assets 150, that a grid asset has connected to the electric grid 103 at a connection point, and in response, the grid monitoring server 130 can send a request to the grid asset for information related to the grid asset.

In some examples, the grid asset that connects to the electric grid 103 is a grid asset that has previously connected to the electric grid 103, and the grid monitoring server updates the status for the previously-connected grid asset in the grid asset database 430 in response to detecting that the grid asset has reconnected to the electric grid 103. For example, the electric vehicle 121 can reconnect to the electric grid 103 after having previously been connected to and subsequently disconnected from the electric grid 103. When the grid monitoring server 130 detects the connection of the electric vehicle 121 to the electric grid 103, the grid monitor 414 can obtain the grid asset status 146 from the electric vehicle 121 and update the grid asset database 430 with the grid asset status 146 by updating the database entry that already exists for the electric vehicle 121.

In some examples, the grid asset that connects to the electric grid 103 is a grid asset that has not previously connected to the electric grid 103, and the grid monitoring server 130 can create a new database entry for the grid asset in response to detecting that the grid asset has connected to the electric grid 103 for the first time. For example, the air conditioner 115 may be newly installed in the office building 116, and when the grid monitoring server 130 detects the connection of the air conditioner 115 to the electric grid 103, the grid monitor 414 can obtain the grid asset status 146 from the air conditioner 115 and update the grid asset database 430 with the grid asset status 146 by adding a new database entry, the air conditioner 115. Creating the new database entry can include requesting, from the air conditioner 115, operating parameters for the air conditioner 115 and adding the operating parameters for the air conditioner 115 to the database entry for the air conditioner 115. The grid monitor 414 can also update the grid asset database with the status of the air conditioner 115, such as whether the air conditioner 115 is powered on or powered off, and if the air conditioner 115 is powered on, the power setting (e.g., low or high) of the air conditioner 115.

The grid asset database 430 can include recorded status information for the grid assets 150. The recorded status information can include a status of the availability of the grid asset to perform grid services. The recorded status information can include an electrical load drawn by the grid asset from the electric grid 103, an electrical power provided by the grid asset to the electric grid 103, an on/off status of the grid asset, a power setting of the grid asset, a standby status of the grid asset, and a status of a connection of the grid asset to the electric grid 103.

In some examples, in addition to or instead of recording the status information for the grid assets 150 in the grid asset database 430, the grid monitor 414 can record the status information in a distributed database. Distributed databases store data across a common network rather than at a centralized location. In some examples, the distributed database is a blockchain network. Blockchain is a distributed database of records or a public ledger of all transactions or digital events that have been executed and shared among participating parties. In a blockchain network, an agent creates a new transaction to be added to the blockchain. This new transaction is transmitted to the network for validation and auditing. When most nodes approve the transaction according to prespecified rules in the chain, the new transaction is added to the chain as a new block. A record of that transaction is stored in multiple nodes distributed for security. To record the status information in a distributed database, each verification or confirmation of availability of a grid asset can be recorded as a transaction or microtransaction in the network.

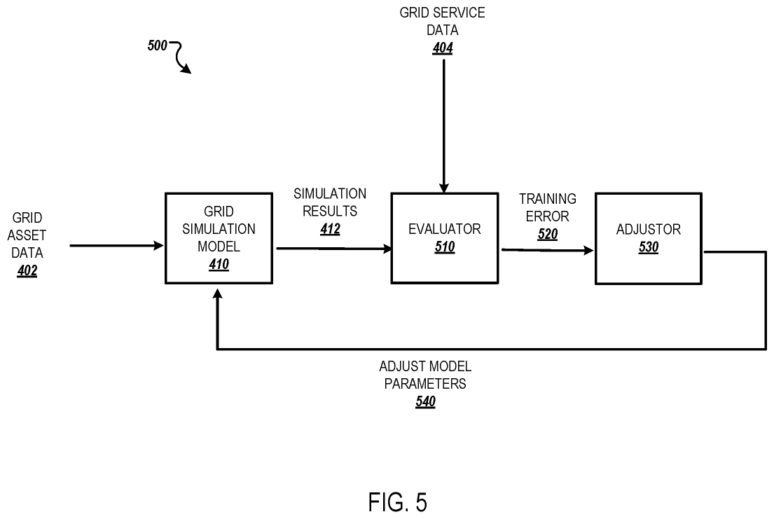

The grid monitoring server 130 includes a grid simulation model 410 that can perform simulations of various grid conditions and events based on grid asset data 402 received from the grid asset database 430. For example, the grid simulation model 410 can perform many (e.g., thousands or millions) of simulations for various types of electric grid events occurring at various locations and times. In some examples, the grid simulation model 410 includes probability functions for determining the probability of whether or not certain grid faults will occur, and the probability of whether or not the grid assets 150 will be capable of maintaining electric grid stability. The probability functions can be trained and improved over time using grid data 446 obtained during operations of the electric grid 103. The grid simulation model 410 can generate simulation results 412, which can include predicted grid services that will be performed by different grid assets 150 during the electric grid events. Processes for training the grid simulation model 410 are described with reference to FIG. 5.

In one example, the grid simulation model 410 performs a simulation of a set of electric grid conditions that includes an overload condition occurring on a particular feeder of the electric grid 103 at a particular time. The grid simulation model 410 can identify demands for grid services during and after the overload condition electric grid event. The grid simulation model 410 can generate simulation results 412 representing electric grid conditions during and after the electric grid event with the grid services performed, and simulation results 412 representing electric grid conditions during and after the electric grid event without the grid services performed. The simulation results 412 can include, for various electric grid events, information identifying demands for grid services that are associated with the electric grid events. For example, the simulation results may indicate that, for the loss of a particular power source at a particular time, fast inertial services are in demand within a range of two miles from the particular power source, for a duration of ten seconds. The simulation results 412 can identify grid assets 150 that are predicted to autonomously provide grid services when the grid event occurs.

The grid simulation model outputs the simulation results 412 to the service value estimation model 420 and to the grid monitor 414. The service value estimation model 420 is configured to simulate the value of various grid services to potentially be performed in the future and generate an estimated service value 421 for various grid services. The estimated service value 421 can be a value for a particular grid service performed by a particular grid asset under a set of electric grid conditions. The estimated service value 421 is a predicted future value of the grid service. The estimated service value 421 can vary based on one or more of the time a grid service is performed by a grid asset, location of the grid asset during performance of the grid service, and environmental conditions at the time and location at which the grid service is performed. For example, the value of the electric vehicle 121 performing fast balancing services when connected to the electric grid 103 at a first location within the electric grid 103 (e.g., through the transformer 106a) may be different from the value of the electric vehicle 121 performing fast balancing services when connected to the electric grid 103 at another location within the electric grid 103 (e.g., through the transformer 106b). Similarly, the value of the electric vehicle 121 performing fast balancing services at night and/or on the weekend may be different from the value of the electric vehicle 121 performing fast balancing services during the daytime and/or during the workweek. The estimated service value 421 generated by the service value estimation model 420 can also vary based on a duration of the grid service. For example, an estimated service value 421 of a grid service performed over a longer duration may be greater than an estimated service value of the same grid service performed over a shorter duration. Additionally, an estimated service value can increase throughout a duration of performance of the grid service. For example, the generator 124 may be predicted to provide emergency power services for a time duration of two hours during a particular electric grid event. The value of the service may increase during the time duration, such that the estimated value of providing emergency power services during the second hour is greater than the estimated value of providing emergency power services during the first hour.

In some examples, the service value estimation model 420 can determine a value for a particular grid service performed by a particular grid asset based in part on a cost to a customer for the grid asset performing the grid service. For example, the refrigerator 109 may be available to perform load shifting services by powering off. The service value estimation model 420 can include functions that model a cost to a customer, such as the owner or resident of the house 118, for powering off the refrigerator 109. The cost to the customer can vary based on a duration of the refrigerator being off, a time of day that the refrigerator is powered off, environmental conditions at the location of the house 118, or any combination thereof. In some examples, the service value estimation model 420 can determine a value for a particular grid service based at least in part on a cost-benefit analysis of the benefit that the grid asset provides to the electric grid and the cost to the customer.

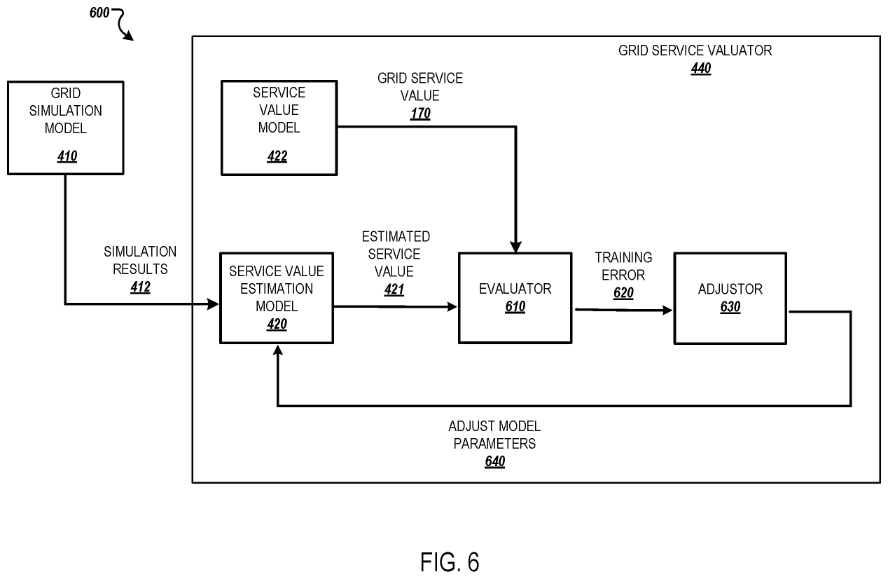

In some examples, the service value estimation model 420 can compare simulation results representing an electric grid event during which a particular grid service is performed to simulation results representing the same electric grid event during which the particular grid service is not performed. Based on the comparison, the service value estimation model 420 can determine the estimated service value 421 for the grid service. In this way, the service value estimation model 420 can use the simulation results 412 to determine effects to the electric grid 103 when the demand for grid services is not satisfied by grid assets, and therefore the value of the demand being satisfied by the grid services provided by grid assets. Processes for training the value estimation are described with reference to FIG. 6.

The service value estimation model 420 provides the estimated service values 421 to the service value model 422. In some examples, the service value model 422 can include functions for determining grid service values for different assets performing different services. The service value model 422 can use the functions to determine the real-time value of the grid services, based in part on the energy market value 154 at the time at which the grid services are performed, and based in part on grid service data 404 provided by the grid monitor 414.

In some implementations, the grid monitor 414 can perform live grid control operations. For example, the grid monitor 414 can include control circuitry and/or can communicate with control devices that enable the grid monitor 414 to control components of the electrical distribution system. The grid monitor 414 can perform live grid control, for example, by sending grid instructions 448 that result in starting up or shutting down components of the electric grid 103. In some examples, the grid monitor 414 can control operations of grid assets 150.

For example, the grid monitor 414 can determine electrical distribution system requirements based on the grid data 446 that is received from the sensors 102, the meters 110, and/or the grid assets 150, and can perform live grid control operations to satisfy the electrical distribution system requirements. For example, the grid monitor 414 can determine instantaneous or present electrical load for the electric grid, forecasted electrical load for the electric grid, or both and can control operations of the grid assets 150 to accommodate the instantaneous or present electrical load and/or forecasted electrical load while satisfying operational requirements and limits of the grid assets 150.

The grid monitor 414 monitors conditions of the grid based on the grid data 446 received from the communication interface 222. The grid data 446 can include, for example, sensor data generated by the sensors 102, meter data generated by the meters 110, and grid asset status data for the grid assets 150. The grid data 446 can include voltage data indicating a measured voltage of the electric grid 103, frequency data indicating a measured frequency of the electric grid 103, and load data indicating an electrical load on the electric grid 103.

The grid monitor 414 identifies electric grid conditions and events based on the grid data 446. For example, the grid monitor 414 can determine, based on the grid data 446, that an electric grid event is occurring or has occurred. The electric grid event can be, for example, a load imbalance, an overload condition, an over-voltage or under-voltage condition, an over-current or under-current condition, an over-frequency or under-frequency condition, current surge, voltage collapse, power flow reversal, or a power outage.

The grid monitor 414 can identify a demand, or demands, for grid services based on detecting the electric grid event. For example, the grid monitor 414 can identify a demand for a type of grid service to be performed, a location for the grid service to be performed, a time for the grid service to be performed, a duration for the grid service to be performed, or any combination of these features. In some examples, the grid monitor 414 receives simulation results from the grid simulation model 410 and identifies the demand for a grid service based on the simulation results 412. For example, the grid monitor 414 can identify simulation results for grid conditions that are similar to, or the same as, present grid conditions, and can identify demands for grid services that are indicated by the simulation results 412.

In some examples, the grid monitor 414 identifies, from the grid asset database 430, a subset of grid assets that are relevant to the electric grid event. The subset of grid assets can be selected based on selection criteria. In some examples, the grid monitor 414 can select grid assets for inclusion in the subset based on the recorded status of the grid assets. For example, the grid monitor 414 can select grid assets that are indicated in the grid asset database as being available to perform grid services that are likely in demand due to the electric grid event. In some examples, the grid monitor 414 selects grid assets for inclusion in the subset based on the locations of the grid assets. For example, the grid monitor 414 can select grid assets that are within a designated proximity to the grid event. In one example, the grid event occurs on a particular feeder of the electric grid 103, and the grid monitor 414 selects grid assets that are on the particular feeder of the electric grid experiencing the grid event. In another example, the grid event occurs at a particular geographical location, and the grid monitor 414 selects grid assets that are within a threshold distance to the grid event (e.g., a half mile, a mile, two miles). The designated proximity can vary based on the type of grid event. For example, for grid events that cause a demand for fast balancing, the designated proximity of grid assets that are relevant to the grid event may be a closer proximity compared to grid events that cause a demand for power storage.

In some examples, the grid monitor 414 determines, for each of the grid assets that are relevant to the electric grid event, whether the grid asset is performing one or more of the grid services that are in demand due to the electric grid event. The grid monitor 414 can determine that grid assets are performing grid services in a number of different ways.

In some examples, the grid monitor 414 can poll each grid asset of the subset that is relevant to the electric grid event in order to identify grid assets that are performing grid services during the electric grid event. For example, during the electric grid event, the grid monitor 414 can request a grid asset status 146 from each of the relevant grid assets. The grid asset status 146 can include, for example, a connection status of the grid asset, a power status of the grid asset, a charge/discharge status of the grid asset, and a power consumption of the grid asset. The grid monitor 414 can determine whether the status of the grid asset corresponds to an expected status of the grid asset when performing the grid service, and, in response to determining that the status of the grid asset corresponds to the expected status, the grid monitor 414 can determine that the grid asset is performing the grid service. In response to determining that the status of the grid asset does not correspond to the expected status, the grid monitor 414 can determine that the grid asset is not performing the grid service.

In some examples, the grid monitor 414 can obtain measurement data for a grid asset from an electric meter associated with the grid asset in order to determine whether the respective grid asset is performing grid services during the electric grid event. The measurement data can represent a measurement taken for the grid asset. In some cases, the grid monitor 414 can determine that the grid asset is performing the grid service based on determining, using the measurement data, that the grid asset is providing electrical power to the electric grid 103 or is receiving electrical power from the electric grid 103.

In some examples, the grid monitor 414 can determine that a grid asset is performing a grid service during the electric grid event based on the availability status of the grid asset at the time when the event occurred. For example, the grid monitor 414 can determine that an electric grid event occurred at a first time, and can access the grid asset database 430 to determine the status of the grid asset at or before the first time. In some cases, the grid monitor 414 accesses the most recent status update for the grid asset prior to the first time when the event occurred. In one example, the grid monitor 414 determines that a particular grid asset was available to perform the grid service at or before a time that the electric grid event occurred, and in response, determines that the grid asset has performed or is currently performing the grid service during the electric grid event. For example, the grid monitor 414 can determine that a grid asset was available in an automatic standby status to perform a grid service of emergency energy supply prior to an event in which emergency energy supply was subsequently needed. In response, the grid monitor 414 can determine that the grid asset automatically initiated supplying emergency energy at the initiation of the event, and can determine that the grid asset performed or is currently performing the grid service of emergency energy supply.

Alternatively, the grid monitor 414 can determine that the grid asset was not available to perform the grid service at or before the time that the electric grid event occurred, and in response, determine that the grid asset did not perform (or is not currently performing) the grid service during the electric grid event. A grid asset may be unavailable to perform a grid service, for example, when the grid asset is powered off or disconnected from the electric grid, when the grid asset is near a maximum load, or for instance a minimum state of charge, and/or does not have capacity for performing the grid service, when the grid asset is performing another grid service that has a higher priority, or any combination thereof.

In some examples, the grid monitor 414 can determine that a grid asset is performing a grid service during an electric grid event based on the grid data 446 and the simulation results 412. The grid data 446 can include, for example, voltage data indicating a measured voltage of the electric grid 103, frequency data indicating a measured frequency of the electric grid 103, load data indicating an electrical load on the electric grid 103, data indicating the type of the grid service being performed, data indicating a location of the grid service being performed, data indicating a start time of the grid service being performed, data indicating a duration of the grid service being performed, or any combination of this data. The grid monitor 414 can determine whether the grid data 446 matches simulation results 412 for grid conditions in which a grid service is being performed or simulation results 412 for grid conditions in which the grid service is not being performed. In response to determining that the grid data 446 more closely matches simulation results 412 for grid conditions in which the grid service is being performed, the grid monitor 414 can determine that the grid service is being performed. In response to determining that the grid data 446 more closely matches simulation results 412 for grid conditions in which the grid service is not being performed, the grid monitor 414 can determine that the grid service is not being performed. For example, the simulation results 412 can include a first set of simulation results for grid conditions in which the generator 124 provides emergency energy services during an electric grid event, and a second set of simulation results for grid conditions in which the generator 124 fails to start during the electric grid event, and therefore does not provide emergency energy services. The grid monitor 414 can determine that the grid data 446 more closely matches the first set of simulation results than the second set of simulation results, and thus, that the generator 124 is providing emergency energy services during the electric grid event. In some examples, the generator provides the emergency energy services by automatically initiating emergency energy services in response to a controller of the generator 124 detecting the electric grid event. In some examples, the generator provides the emergency energy services in response to receiving an instruction from another component, such as the grid monitoring server 130, that causes the generator to provide the emergency energy services.

The grid monitor 414 can identify, based on the grid asset status 146 and other grid data 446, grid assets that have autonomously responded to the grid event and are performing grid services. In some examples, the grid monitor 414 can update the grid asset database 430 with the status of the grid assets that are performing the grid services.

In some examples, the grid monitor 414 can determine that additional demand exists for grid services. For example, the grid monitor 414 can determine, based on the grid data 446 and the simulation results 412, that the grid services being performed by grid assets during an electric grid event are not sufficient to maintain grid stability. In response to determining that additional demand exists for grid services, the grid monitor 414 can identify, from the grid asset database 430, additional grid assets that are available to perform grid services. In some examples, the grid monitor 414 selects one or more grid assets from the grid asset database 430 to perform grid services based on the operating parameters for the grid assets, the recorded status information for the grid assets, the location of each of the grid assets relative to the electric grid 103, the location of each of the grid assets relative to the electric grid event, or any combination of these features.

In some examples, the grid monitor 414 selects a first grid asset for performing a grid service, such as by selecting the battery 122 for performing emergency energy supply services. The grid monitor 414 can select the battery 122 based on status information in the grid asset database 430 that indicates a recent charge level of 100% for the battery. The grid monitor 414 can send, to the battery 122, a request for updated status information, and in response, receive grid asset status data 146 indicating a current charge level of 50% for the battery 122. The grid monitor 414 may therefore determine that the battery 122 does not have sufficient charge to perform the grid service. In response to determining that the battery 122 does not have sufficient charge to perform the grid service, the grid monitor 414 can select another grid asset to provide the grid service. For example, the grid monitor 414 can select the generator 124 to provide the grid service of emergency energy supply.

The grid monitor 414 outputs grid instructions 448 to the grid assets 150 through the communication interface 222. The grid instructions 448 can include instructions that cause a change in status, or maintenance of a status, of one or more grid assets 150. For example, the grid instructions 448 can include an instruction to the generator 124 to start up and to connect to the electric grid 103. In some examples, the grid instructions 448 include an instruction for a grid asset to connect to the electric grid 103, an instruction for a grid asset to disconnect from the electric grid 103, an instruction for a grid asset to power off, an instruction for a grid asset to power on, an instruction for a grid asset to change a power setting, or any combination of these instructions. In some examples, the grid instructions 448 can cause switches and/or breakers of the electric grid 103 to change status. For example, the grid instructions 448 can cause a set of switches to reconfigure in order to island a microgrid of the electric grid 103. The grid monitor 414 can determine to island the microgrid, for example, based on determining that grid assets are available to power the microgrid. A microgrid is a local electrical grid with defined electrical boundaries, acting as a single and controllable entity. A microgrid is able to operate in grid-connected and in island mode. A grid-connected microgrid normally operates connected to and synchronous with the wide-area electric grid, but is able to disconnect from the interconnected grid in order to function autonomously in island mode as technical or economic conditions dictate. Microgrids can be used to improve the security of supply within the microgrid cell, and can supply emergency power, changing between island and connected modes.

The grid monitor 414 can monitor grid assets performing grid services over time. For example, the grid monitor 414 can use the grid data 446 to determine when grid assets start and stop performing grid services. The grid monitor 414 outputs grid service data 404, indicating grid services that are being performed by grid assets 150, to the grid service valuator 440. The grid service valuator 440 determines a grid service value 170 based on the grid service data 404, the simulation results 412, and the energy market value 154. The grid service valuator 440 receives the energy market value 154 from the energy market data source 155 through the communication interface 222. The energy market value 154 indicates a market value of energy provided by the electric grid 103. In some examples, the energy market data corresponds to a type of electric grid event that occurred and the type of grid service provided.

In some examples, the service value model 422 of the grid service valuator 440 uses the estimated service value 421 as a base value, and adjusts the estimated service value 421 based on the grid service data 404 and the energy market value 154. For example, the estimated service value 421 can be based on a particular grid asset performing a particular service for a particular length of time under particular grid conditions. The service value model 422 can adjust the estimated service value 421 to reflect actual conditions indicated by the grid service data 404 and energy market value 154 in order to generate the grid service value 170. In one example, the service value estimation model 420 generates an estimated service value 421 based on simulation results 412 that include the air conditioner 115 providing load shifting services for two hours on a Tuesday afternoon in response to an overload condition on a feeder of the electric grid 103. During an electric grid event, the grid monitor provides the service value model 422 with grid service data 404 that indicates that the air conditioner 115 performs load shifting services for one hour on a Saturday morning (e.g., by turning off or remaining off) in response to an overload condition on the feeder. The service value model 422 can use the estimated service value 421 as a base value, and adjust the value to account for the difference in the time and duration of the air conditioner 115 providing the grid service modeled in the estimated service value 421 and the time and duration that the air conditioner 115 provided the grid service during the grid event as indicated in the grid service data 404. The service value model 422 can also adjust the value to account for any difference between simulated energy market value used to generate the estimated service value 421 and the actual energy market value 154 at the time the grid service is performed by the air conditioner 115.

Because the estimated service value 421 is determined prior to occurrence of the electric grid event using simulation data, the grid service value 170 can be determined in real time or near-real time. The service value model 422 can determine multiple grid service values 170 for various grid assets 150 performing various grid services simultaneously. In some examples, in addition to or instead of determining grid service values 170 in real-time, the service value model 422 can determine a total grid service value 170 for the grid asset performing the grid service after the grid service is complete.

The service value model 422 can determine the grid service value 170 based on a number of factors. For example, the service value model 422 can determine the value for a grid service performed by a grid asset based at least in part on a response time of the grid asset. For example, the service value model 422 may determine a higher value for a faster response time, and a lower value for a slower response time.

In some examples, the service value model 422 determines the value for a grid service based at least in part on the duration of the grid asset performing the grid service. For example, the service value model 422 may determine a higher value for grid services that are provided for a longer duration, and a lower value for grid services that are provided for a shorter duration.

In some examples, the service value model 422 determines the value for a grid service based at least in part on a location of a connection point of the grid asset to the electric grid 103. For example, the service value model 422 may determine a higher value for services provided at or near an end of a feeder of the electric grid 103, and a lower value for services provided at or near a middle of a feeder of the electric grid 103.

In some examples, the service value model 422 assigns a higher value for grid services that enable prioritization of high priority loads. For example, the service value model 422 may assign a higher value for providing emergency energy services that enable maintaining power to a hospital, and a lower value for providing emergency energy services that enable maintaining power to a residential area.

The service value model 422 can determine the value for a grid service based at least in part on a number of grid assets that are available to perform the grid service. For example, in a scenario in which many grid assets are available to perform the grid service, the service value model 422 may assign a lower value to the performance of the grid service compared to a scenario in which only one grid asset is available to perform the grid service.

Still referring to FIG. 4, the service value model 422 provides the grid service value 170 to the account management server 160 via the communication interface 222. The grid service value 170 can be provided, for example, as a value of currency per time increment that the grid service is performed, a total value of currency for performance of the grid service, an energy credit per time increment that the grid service is performed, a total energy credit for performance of the grid service, a time-varying value over a duration of performance of the grid service, or any combination of these values.

In some implementations, one or more of the grid simulation model 410, the service value estimation model 420, and the service value model 422 includes a machine learning model that can be trained using training data. The training data can include many (e.g., millions) training samples. In some implementations, a machine learning model is a deep learning model that employs multiple layers of models to generate an output for a received input. A deep neural network is a deep machine learning model that includes an output layer and one or more hidden layers that each applies a non-linear transformation to a received input to generate an output. In some cases, the neural network may be a recurrent neural network. A recurrent neural network is a neural network that receives an input sequence and generates an output sequence from the input sequence. In particular, a recurrent neural network uses some or all of the internal state of the network after processing a previous input in the input sequence to generate an output from the current input in the input sequence. In some implementations, a machine learning model is a convolutional neural network. In some implementations, the machine learning model is an ensemble of models that may include all or a subset of the architectures described above.

In some implementations, the machine learning model can be a feedforward autoencoder neural network. For example, the machine learning model can be a threelayer autoencoder neural network. The machine learning model may include an input layer, a hidden layer, and an output layer. In some implementations, the neural network has no recurrent connections between layers. Each layer of the neural network may be fully connected to the next, there may be no pruning between the layers. The neural network may include an ADAM optimizer, or any other multi-dimensional optimizer, for training the network and computing updated layer weights. In some implementations, the neural network may apply a mathematical transformation, such as a convolutional transformation, to input data prior to feeding the input data to the network.

In some implementations, the machine learning model can be a supervised model. For example, for each input provided to the model during training, the machine learning model can be instructed as to what the correct output should be. The machine learning model can use batch training, training on a subset of examples before each adjustment, instead of the entire available set of examples. This may improve the efficiency of training the model and may improve the generalizability of the model. The machine learning model may use folded cross-validation. For example, some fraction (the “fold”) of the data available for training can be left out of training and used in a later testing phase to confirm how well the model generalizes. In some implementations, the machine learning model may be an unsupervised model. For example, the model may adjust itself based on mathematical distances between examples rather than based on feedback of its performance.

FIG. 5 is a diagram of a system 500 for training the grid simulation model 410. In some examples, the grid simulation model 410 is a machine learning model, such as a convolutional neural network model (e.g., an autoencoder model). The grid simulation model 410 can be trained by simulating grid conditions and operations, and comparing the simulation results with actual grid conditions and operations. Over time, the grid simulation model 410 is trained to become more accurate at predicting grid services that will be performed by grid assets at various electric grid conditions and during various electric grid events. The grid simulation model 410 can be trained using a set of ground truth data that includes grid service data 404 representing performance of grid services by grid assets. The grid service data 404 represents actual performance of grid services by grid assets in various conditions.

The grid simulation model 410 receives input data that includes grid asset data 402 from the grid asset database 430. The grid asset data 402 can include representations of the grid assets 150 that are connectable to the electric grid 103. The grid simulation model 410 processes the grid asset data to generate corresponding output data, including simulation results 412. The simulation results 412 can represent grid services that the grid assets 150 are predicted to perform at various electric grid conditions. The simulation results 412 can include, for example, an identifier for a grid asset that is predicted to perform a service, a type of grid service expected to be performed by the grid asset, a time duration of performance of the grid service, or any combination of these predictions.

The output data is compared to the ground truth data, and parameters of the grid simulation model 410 are adjusted based on comparing the output data to the ground truth data. For example, an evaluator 510 compares the simulation results 412 to the grid service data 404 and determines a training error 520 between the simulation results 412 and the grid service data 404.

The training error 520 between the simulation results 412 and the grid service data 404 can include different types of errors. For example, a first type of error can occur when the grid simulation model 410 outputs simulation results 412 including a predicted grid service that the grid service data 404 indicates did not occur during the grid event. Another type of error can occur when the simulation model 410 outputs simulation results 412 that do not include a predicted grid service 412 for a grid service that the grid service data 404 indicates occurred during the grid event. Another type of error can occur when the simulation model 410 predicts that a particular grid asset, or type of grid asset, performs a particular grid service, and the particular grid asset or type of grid asset does not match the grid asset that actually performed the grid service, as indicated in the grid service data 404. Other types of error can include an incorrect duration, start time, or time duration of a grid service.

Parameters of the grid simulation model 410 can be adjusted based on comparing the simulation results 412 to the grid service data 404. For example, the adjustor 530 can adjust model parameters 540 based on the training error 520. Model parameters can include, for example, configuration variables, neural network weights, support vectors, and coefficients of the model. Model parameters can also include, for example, threshold and ranges that are applied to various rules within the grid simulation model 410. By adjusting the model parameters based on the training error 520, the grid simulation model 410 can be trained to more accurately predict services performed by assets of the electric grid 103.

FIG. 6 is a diagram of a system 600 for training a service value estimation model 420. In some examples, the service value estimation model 420 is a machine learning model such as a convolutional neural network model (e.g., an autoencoder model). The service value estimation model 420 can be trained using a set of ground truth data that includes grid service value data 170 representing values of grid services performed by grid assets.

The service value estimation model 420 receives input data that includes simulation results 412 that can include representations of services that are predicted to be performed by grid assets 150 that are connectable to the electric grid 103. The simulation results 412 can be provided as output from the grid simulation model 410.

The service value estimation model 420 generates corresponding output data that includes an estimated service value 421. The estimated service value 421 represents an estimated value of the simulation results 412. The estimated service value 421 can include, for example, a value of currency per time increment that the grid service is performed, a total value of currency for performance of the grid service, an energy credit per time increment that the grid service is performed, a total energy credit for performance of the grid service, a time-varying value over a duration of performance of the grid service, or any combination of these values.

The output data is compared to the ground truth data, and parameters of the service value estimation model 420 are adjusted based on comparing the output data to the ground truth data. For example, the evaluator 610 compares the estimated service value 421 to a grid service value 170 that represents the actual value of grid services performed by grid assets and determines a training error 620 between the estimated service value 421 and the grid service value 170, and the adjustor 630 can adjust model parameters 640 of the service value estimation model 420 based on the training error 620. Model parameters 640 can include, for example, configuration variables, neural network weights, support vectors, and coefficients of the model. Model parameters can also include, for example, threshold and ranges that are applied to various rules within the service value estimation model 420. By adjusting the model parameters based on the training error 620, the service value estimation model 420 can be trained to more accurately predict values of services performed by assets of the electric grid 103.

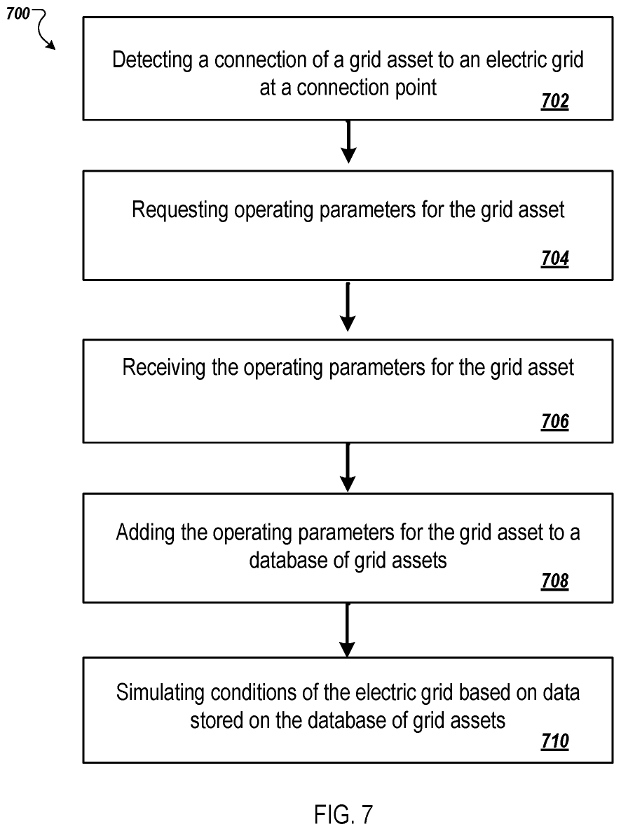

FIG. 7 is a flowchart of an example process 700 for creating a database of grid assets for providing grid services. The process 700 can be performed by a computing system including one or more computers, e.g., grid monitoring server 130. The order of steps in the process 700 is illustrative only, and the steps can be performed in different orders and/or in parallel. In some implementations, the process 700 can include additional steps, fewer steps, or some of the steps can be divided into multiple steps. In some examples, the steps of the process 700 can be performed by different components of the disclosed systems. For example, some steps can be performed by the grid monitoring server 130, and other steps can be performed by any of the sensors 102, the meters 110, the grid assets 150, the account management server 160, and the energy market data source 155.

The process 700 for creating a database of grid assets for providing grid services includes detecting a connection of a grid asset to an electric grid at a connection point (702). The grid asset can be, for example, a distributed energy resource, an inverter-connected resource, an electrical load, an electrical power supply, an electric vehicle, an energy storage resource, or any combination of thereof. Grid services provided by grid assets can include, for example, electrical energy storage, load shifting, fast balancing, peak shaving, frequency regulation, frequency response, voltage regulation, power factor correction, reactive power injection, reactive power absorption, active power injection; emergency energy supply, and inertial service.

The process 700 includes requesting operating parameters for the grid asset (704). For example, the grid monitoring server 130 can transmit, to the grid asset, a request for operating parameters of the grid asset. The operating parameters for the grid asset can include, for example, a power rating of the grid asset, a load capacity of the grid asset, a voltage rating of the grid asset, a voltage rating of the connection point, a current rating of the grid asset, a response time of the grid asset, or any combination of these parameters.

The process 700 includes receiving the operating parameters for the grid asset (706). For example, the grid monitoring server 130 can receive, from the grid asset, a communication indicating the operating parameters for the grid asset. In some examples, the grid monitoring server 130 can receive the operating parameters for the grid asset from a component other than the grid asset. For example, an electric meter can be configured to generate electrical measurements representing operating parameters for the grid asset, and the electric meter can transmit the electrical measurements to the grid monitoring server 130.

The process 700 includes adding the operating parameters for the grid asset to a database of grid assets (708). In some examples, the grid monitoring server 130 adds an identifier for the grid asset to the database of grid assets. In some examples, after adding the identifier for the grid asset to the database of grid assets, the grid monitoring server 130 can request a status of the grid asset. For example, the grid monitoring server 130 can transmit, to the grid asset, a request for status information for the grid asset and receive, from the grid asset, a response to the request including the status information. The status information for the grid asset can include, for example, an electrical load drawn by the grid asset from the electric grid 103, an electrical power provided by the grid asset to the electric grid 103, an on/off status of the grid asset, a power setting of the grid asset, a standby status of the grid asset, a status of the connection of the grid asset to the electric grid 103, or any combination of these statuses.

The grid monitoring server 130 can determine, based on the status information for the grid asset, an availability of the grid asset to perform a grid service. In some examples, the grid monitoring server 130 can record, in a distributed database, the availability of the grid asset to perform the grid service. In some examples, the grid monitoring server 130 can determine that the grid asset is not available to perform the grid service. In response to determining that the grid asset is not available to perform the grid service, the grid monitoring server 130 can select another grid asset to provide the grid service. The process 700 includes simulating conditions of the electric grid based on data stored on the database of grid assets (710). For example, the grid monitoring server 130 can perform simulations to obtain simulation results based on data stored on the grid asset database that corresponds to the grid assets.

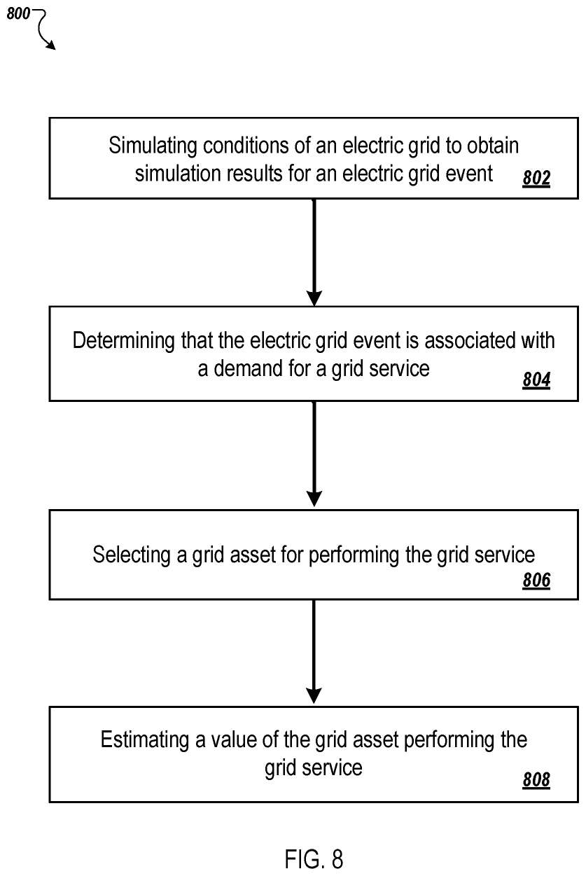

FIG. 8. is a flowchart of an example process 800 for estimating the value of grid services based on simulation results. The process 800 can be performed by a computing system including one or more computers, e.g., grid monitoring server 130. The order of steps in the process 800 is illustrative only, and the steps can be performed in different orders and/or in parallel. In some implementations, the process 800 can include additional steps, fewer steps, or some of the steps can be divided into multiple steps. In some examples, the steps of the process 800 can be performed by different components of the disclosed systems. For example, some steps can be performed by the grid monitoring server 130, and other steps can be performed by any of the sensors 102, the meters 110, the grid assets 150, the account management server 160, and the energy market data source 155.

The process 800 includes simulating conditions of an electric grid to obtain simulation results for an electric grid event (802). For example, the grid monitoring server 130 can perform simulations based on data stored in a database of grid assets connected to the electric grid 103. The electric grid event can be, for example, a grid fault, a load imbalance, an overload condition, an over-voltage or under-voltage condition, an over-current or under-current condition, an over-frequency or under-frequency condition, current surge, voltage collapse, power flow reversal, a power outage, or any combination of these conditions.

The process 800 includes determining that the simulated electric grid event is associated with a demand for a particular grid service (804). For example, the grid monitoring server 130 can determine, based on the simulation results, that the simulated electric grid event is associated with a demand for a particular grid service.

The process 800 includes selecting a grid asset for performing the particular grid service (806). For example, the grid monitoring server 130 can access a database of grid assets that are electrically connected to the electric grid 103 and, the grid monitoring server 130 can select a grid asset from the database based at least in part on a status of the grid asset, a location of the grid asset relative to the electric grid 103, a location of the grid asset relative to a location of the electric grid event, or any combination of these features.

The process 800 includes estimating a value of the grid asset performing the grid service (808). For example, the grid monitoring server 130 can estimate the value of the grid asset performing the grid service based on the simulation results for the simulated electric grid event. A value for a grid service can include, for example, a value of currency per time increment that the grid service is performed, a total value of currency for performance of the grid service, an energy credit per time increment that the grid service is performed, a total energy credit for performance of the grid service, a time-varying value over a duration of performance of the grid service, or any combination of these values.

In some examples, estimating the value of the grid asset performing the grid service includes simulating conditions of the electric grid 103. For example, the grid monitoring server 130 can simulate the electric grid event with the grid service performed, to obtain a second set of simulation results. The grid monitoring server 130 can compare the second set of simulation results to the simulation results of the electric grid event without the grid service being performed.

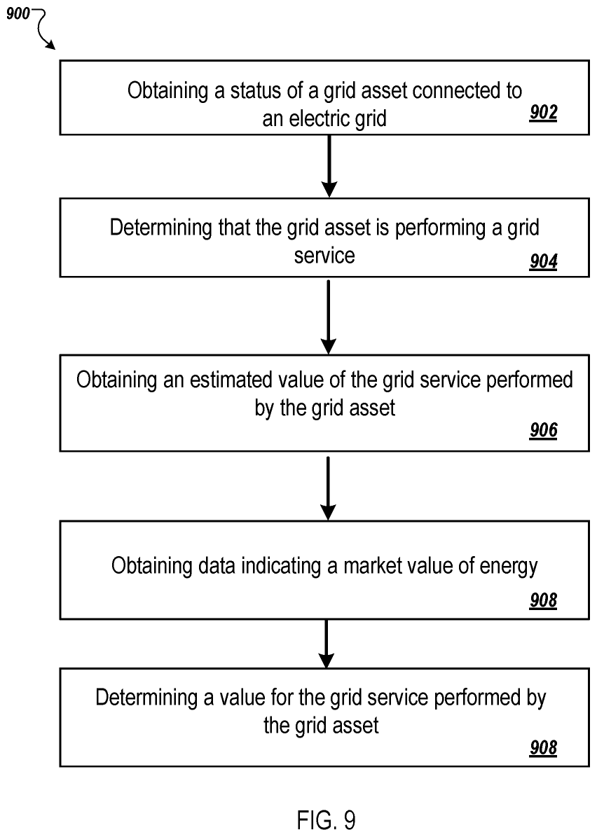

FIG. 9 is a flowchart of an example process 900 for determining the value of a grid service performed by a grid asset. The process 900 can be performed by a computing system including one or more computers, e.g., grid monitoring server 130. The order of steps in the process 900 is illustrative only, and the steps can be performed in different orders and/or in parallel. In some implementations, the process 900 can include additional steps, fewer steps, or some of the steps can be divided into multiple steps. In some examples, the steps of the process 900 can be performed by different components of the disclosed systems. For example, some steps can be performed by the grid monitoring server 130, and other steps can be performed by any of the sensors 102, the meters 110, the grid assets 150, the account management server 160, and the energy market data source 155.

The process 900 includes obtaining a status of a grid asset connected to an electric grid (902). For example, the grid monitoring server 130 can obtain the data indicating the status of the grid asset directly from the grid asset or from an electric meter associated with the grid asset. The data can include measurement data representing a measurement taken for the grid asset. In some examples, obtaining the data indicating the status of the grid asset includes accessing a database of grid assets including recorded status information for grid assets.

The process 900 includes determining that the grid asset is performing a grid service (904). For example, the grid monitoring server 130 can determine that the grid asset is performing the grid service based on the status of the grid asset. In some examples, the grid monitoring server 130 can determine, using the measurement data, that the grid asset is performing a service of providing electrical power to the electric grid or is receiving electrical power from the electric grid. In some examples, the grid monitoring server 130 can determine that the grid asset is performing the grid service based on voltage data indicating a measured voltage of the electric grid 103, frequency data indicating a measured frequency of the electric grid 103, load data indicating an electrical load on the electric grid 103, or any combination thereof. In some examples, the grid asset can initiate performing the grid service automatically, such as in response to a controller of the grid asset detecting an electric grid event. In some examples, the grid asset can initiate performing the grid service on-demand, such as in response to receiving an instruction from the grid monitoring server 130 to perform the grid service.

In some examples, the grid monitoring server 130 can determine that an electric grid event occurred at a first time and that the electric grid event is associated with a demand for a particular grid service. The grid monitoring server 130 can identify a set of grid assets that are relevant to the electric grid event, including the grid asset. The grid monitoring server 130 can determine, based on information recorded in a distributed database, that the grid asset was available to perform the grid service at or before the first time when the electric grid event occurred. The grid monitoring server 130 can determine that the status of the grid asset matches an expected status of the grid asset when performing the grid service. Based on determining that the grid asset is relevant to the grid event, the grid asset was available to perform the grid service when the electric grid event occurred, and the status of the grid asset matches the expected status, the grid monitoring server 130 can determine that the grid asset is performing the grid service. In some examples, the grid monitoring server 130 can identify a type of the grid service being performed, a location of the grid service being performed, a start time of the grid service being performed, a duration of the grid service being performed, or any combination of these features.

The process 900 includes obtaining an estimated value of the grid service performed by the grid asset (906). In some examples, the estimated value is based at least in part on an electrical location of the grid asset relative to the electric grid 103. In some examples, the estimated value of the grid service is based on simulation results. For example, the grid monitoring server 130 can simulate conditions of the electric grid 103 with the grid service performed to obtain first simulation results, and simulate conditions of the electric grid without the grid service performed to obtain second simulation results, and can estimate the value of the grid service based on comparing the first simulation results to the second simulation results.

The process 900 includes obtaining data indicating a market value of energy provided by the electric grid (908). In some examples, the data is energy market data that corresponds to a type of the electric grid event that occurred and the type of grid service provided.

The process 900 includes determining a value for the grid service performed by the grid asset (910). For example, the grid monitoring server 130 can determine the value for the grid service based on the estimated value of the grid service and based on the energy market data. In some examples, the grid monitoring server 130 can determine the value for the grid service based at least in part on a response time of the grid asset, a duration of the grid asset performing the grid service, a location of a connection point of the grid asset to the electric grid, a number of grid assets available to perform the grid service, or any combination of these features.

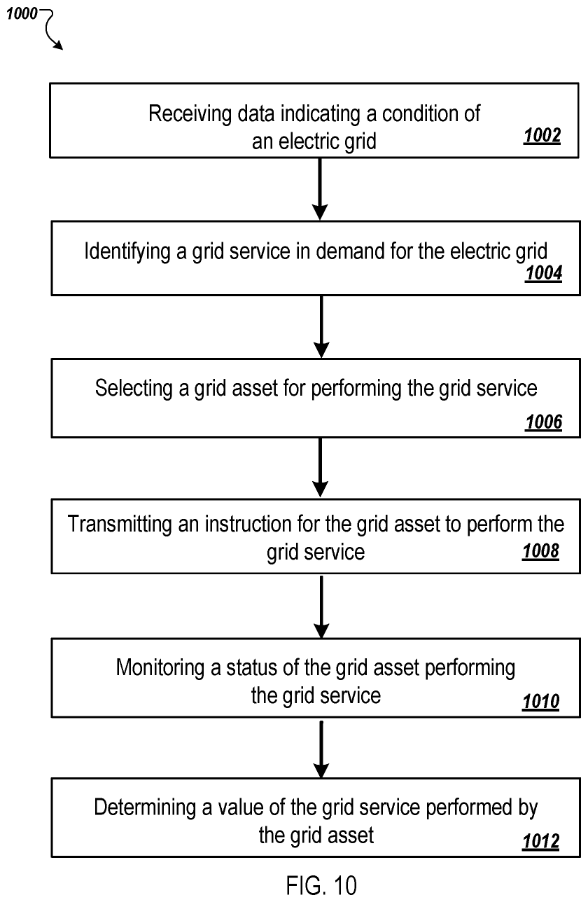

FIG. 10 is a flowchart of an example process 1000 for assigning grid assets to perform grid services. The process 1000 can be performed by a computing system including one or more computers, e.g., grid monitoring server 130. The order of steps in the process 1000 is illustrative only, and the steps can be performed in different orders and/or in parallel. In some implementations, the process 1000 can include additional steps, fewer steps, or some of the steps can be divided into multiple steps. In some examples, the steps of the process 1000 can be performed by different components of the disclosed systems. For example, some steps can be performed by the grid monitoring server 130, and other steps can be performed by any of the sensors 102, the meters 110, the grid assets 150, the account management server 160, and the energy market data source 155.

The process 1000 includes receiving data indicating a current condition of an electric grid (1002). The data indicating the condition of the electric grid can include, for example, voltage data indicating a measured voltage of the electric grid, frequency data indicating a measured frequency of the electric grid, load data indicating an electrical load on the electric grid, or any combination of these features.

The process 1000 includes identifying a grid service in demand for the electric grid (1004). Identifying the grid service in demand can include identifying a type of grid service to be performed, identifying a location for the grid service to be performed, identifying a time for the grid service to be performed, identifying a duration for the grid service to be performed, or any combination thereof.

The process 1000 includes selecting a grid asset for performing the grid service (1006). For example, the grid monitoring server 130 can access a database of grid assets. The database can include, for each of multiple grid assets, an identifier for the grid asset and operating parameters for the grid asset. The grid monitoring server 130 can select the grid asset for performing the grid service based on the operating parameters stored on the database. In some examples, the database of grid assets includes recorded status information for the grid assets, and the grid monitoring server can select the grid asset based on the recorded status information for the grid asset.

The process 1000 includes transmitting an instruction for the selected grid asset to perform the grid asset (1008). The instruction to perform the grid service can include, for example, an instruction to connect to the electric grid, an instruction to disconnect from the electric grid, an instruction to power off, an instruction to power on, an instruction to change a power setting of the grid asset, or any combination of these instructions.

The process 1000 includes monitoring a status of the grid asset performing the grid service (1010). For example, the grid monitoring server 130 can receive updated status information from the grid asset while the grid asset performs the grid service, after the grid asset performs the grid service, or both.

The process 1000 includes determining a value of the grid service performed by the grid asset (1012). For example, the grid monitoring server 130 can determine the value for the grid service performed by the grid asset based on a response time of the grid asset, a duration of the grid asset performing the grid service, a location of a connection point of the grid asset to the electric grid, a number of grid assets available to perform the grid service, or any combination of these features.

One innovative aspect of the subject matter described in this specification is embodied in methods that include the actions of: detecting a connection of a grid asset to an electric grid at a connection point; receiving, from the grid asset, a communication indicating operating parameters for the grid asset; adding, to a database of grid assets, an identifier for the grid asset and the operating parameters for the grid asset; and simulating conditions of the electric grid based on data corresponding to a plurality of grid assets, the data being stored in the database and including the operating parameters for the grid asset.

These and other embodiments can include the following features, alone or in any combination. In some implementations, the method includes transmitting, to the grid asset, a request for operating parameters for the grid asset; and receiving, from the grid asset, the communication indicating the operating parameters for the grid asset in response to transmitting the request.

In some implementations, receiving the communication indicating the operating parameters for the grid asset includes receiving the communication from the grid asset in response to the grid asset connecting to the electric grid.

In some implementations, the operating parameters for the grid asset include at least one of a group consisting of: a power rating of the grid asset; a load capacity of the grid asset; a voltage rating of the grid asset; a voltage rating of the connection point; a current rating of the grid asset; and a response time of the grid asset.

In some implementations, the method includes: after adding the identifier for the grid asset to the database of grid assets, transmitting, to the grid asset, a request for status information for the grid asset; receiving, from the grid asset, a response to the request, the response including the status information for the grid asset; and determining, based on the status information for the grid asset, an availability of the grid asset to perform a grid service.

In some implementations, the method includes recording, in a distributed database, the availability of the grid asset to perform the grid service.

In some implementations, the status information for the grid asset includes at least one of a group consisting of: an electrical load drawn by the grid asset from the electric grid; an electrical power provided by the grid asset to the electric grid; an on/off status of the grid asset; a power setting of the grid asset; a standby status of the grid asset; and a status of the connection of the grid asset to the electric grid.

In some implementations, the method includes: determining that the grid asset is not available to perform the grid service; and in response to determining that the grid asset is not available to perform the grid service, selecting another grid asset to provide the grid service.

In some implementations, the grid service includes at least one of a group consisting of: electrical energy storage; load shifting; fast balancing; peak shaving; frequency regulation; frequency response; voltage regulation; reactive power injection; reactive power absorption; active power injection; emergency energy supply; and inertial service.

In some implementations, the grid asset includes at least one of a group consisting of: a distributed energy resource; an inverter-connected resource; an electrical load; an electrical power supply; an electric vehicle; and an energy storage resource.

One innovative aspect of the subject matter described in this specification is embodied in methods that include the actions of: simulating conditions of an electric grid to obtain simulation results, including simulating an electric grid event; determining, based on the simulation results, that the simulated electric grid event is associated with a demand for a grid service for the electric grid; accessing a database of grid assets electrically connected to the electric grid, the database including for each grid asset of a plurality of grid assets: an identifier for the grid asset; and operating parameters for the grid asset; selecting, from the plurality of grid assets and based on the operating parameters for the grid assets, a grid asset for performing the grid service; and estimating a value of the grid asset performing the grid service.

These and other embodiments can include the following features, alone or in any combination. In some implementations, estimating the value of the grid asset performing the grid service includes: simulating conditions of the electric grid, including simulating the electric grid event with the grid service performed, to obtain second simulation results; and comparing the second simulation results to the simulation results.

In some implementations, the method includes selecting the grid asset based on at least one of a group consisting of: a status of the grid asset; a location of the grid asset relative to the electric grid; and a location of the grid asset relative to a location of the electric grid event.

In some implementations, the method includes obtaining data indicating a status of a grid asset connected to an electric grid; determining, based on the status of the grid asset, that the grid asset is performing the grid service; obtaining energy market data indicating a market value of energy provided by the electric grid; and determining a value for the grid service performed by the grid asset based on (a) the estimated value of the grid service performed by the grid asset and (b) the energy market data.

In some implementations, the value for the grid service includes at least one of a group consisting of: a value of currency per time increment that the grid service is performed; a total value of currency for performance of the grid service; an energy credit per time increment that the grid service is performed; a total energy credit for performance of the grid service; and a time-varying value over a duration of performance of the grid service.

In some implementations, the operating parameters for the grid asset include at least one of a group consisting of: a power rating of the grid asset; a load capacity of the grid asset; a voltage rating of the grid asset; a voltage rating of the connection point; a current rating of the grid asset; and a response time of the grid asset.

In some implementations, the grid service includes at least one of a group consisting of: electrical energy storage; load shifting; fast balancing; peak shaving; frequency regulation; frequency response; voltage regulation; reactive power injection; reactive power absorption;

In some implementations, the grid asset includes at least one of a group consisting of: a distributed energy resource; an inverter-connected resource; an electrical load; an electrical power supply; an electric vehicle; and an energy storage resource.

In some implementations, the electric grid event includes at least one of a group consisting of: a grid fault; a load imbalance; an overload condition; an over-voltage condition; an under-voltage condition; an over-current condition; an under-current condition; an over-frequency condition; an under-frequency condition; a current surge; a voltage collapse; a power flow reversal; and a power outage.

One innovative aspect of the subject matter described in this specification is embodied in methods that include the actions of obtaining data indicating a status of a grid asset connected to an electric grid; determining, based on the status of the grid asset, that the grid asset is performing a grid service; obtaining an estimated value of the grid service performed by the grid asset; obtaining energy market data indicating a market value of energy provided by the electric grid; and determining a value for the grid service performed by the grid asset based on (a) the estimated value of the grid service performed by the grid asset and (b) the energy market data.

These and other embodiments can include the following features, alone or in any combination. In some implementations, estimating the value of the grid asset performing the grid service includes: obtaining the data indicating the status of the grid asset includes obtaining, from an electric meter associated with the grid asset, measurement data representing a measurement taken for the grid asset.

In some implementations, determining that the grid asset is performing the grid service includes determining, using the measurement data, that the grid asset is providing electrical power to the electric grid or is receiving electrical power from the electric grid.

In some implementations, determining that the grid asset is performing the grid service includes: determining that an electric grid event occurred at a first time, the electric grid event being associated with a demand for the grid service; identifying a set of grid assets that are relevant to the electric grid event, the set of grid assets including the grid asset; determining, based on information recorded in a distributed database, that the grid asset was available to perform the grid service at or before the first time; and determining that the status of the grid asset matches an expected status of the grid asset when performing the grid service.

In some implementations, the energy market data corresponds to a type of the electric grid event that occurred and the type of grid service provided.

In some implementations, the electric grid event includes at least one of a group consisting of: a grid fault; a load imbalance; an overload condition; an over-voltage condition; an under-voltage condition; an over-current condition; an under-current condition; an over-frequency or under-frequency condition; a current surge; a voltage collapse; a power flow reversal; and a power outage.

In some implementations, the estimated value of the grid service performed by the grid asset is based at least in part on an electrical location of the grid asset relative to the electric grid.

In some implementations, obtaining the estimated value of the grid service includes simulating conditions of the electric grid, including: simulating conditions of the electric grid without the grid service performed to obtain first simulation results; simulating conditions of the electric grid with the grid service performed to obtain second simulation results; and estimating the value of the grid service based on comparing the first simulation results to the second simulation results.

In some implementations, the method includes determining the value for the grid service performed by the grid asset based on at least one of a group consisting of: a response time of the grid asset; a duration of the grid asset performing the grid service; a location of a connection point of the grid asset to the electric grid; and a number of grid assets available to perform the grid service.

In some implementations, the method includes determining that the grid asset is performing the grid service based on at least one of a group consisting of: voltage data indicating a measured voltage of the electric grid; frequency data indicating a measured frequency of the electric grid; and load data indicating an electrical load on the electric grid.

In some implementations, obtaining the data indicating the status of the grid asset includes accessing a database of grid assets including recorded status information for a plurality of grid assets including the grid asset.

In some implementations, the recorded status information for the plurality of grid assets includes, for each grid asset, at least one of a group consisting of: an electrical load drawn by the grid asset from the electric grid; an electrical power provided by the grid asset to the electric grid; an on/off status of the grid asset; a power setting of the grid asset; a standby status of the grid asset; and a status of a connection of the grid asset to the electric grid.

In some implementations, determining that the grid asset is performing a grid service includes at least one of a group consisting of: identifying a type of the grid service being performed; identifying a location of the grid service being performed; identifying a start time of the grid service being performed; and identifying a duration of the grid service being performed.

In some implementations, the value for the grid service includes at least one of a group consisting of: a value of currency per time increment; a total value of currency for performance of the grid service; an energy credit per time increment; a total energy credit for performance of the grid service; and a time-varying value over a duration of performance of the grid service.

In some implementations, the grid service includes at least one of a group consisting of: electrical energy storage; load shifting; fast balancing; peak shaving; frequency regulation; frequency response; voltage regulation; reactive power injection; reactive power absorption; active power injection; emergency energy supply; and inertial service.

In some implementations, the grid asset includes at least one of a group consisting of: a distributed energy resource; an inverter-connected resource; an electrical load; an electrical power supply; an electric vehicle; and an energy storage resource.

One innovative aspect of the subject matter described in this specification is embodied in methods that include the actions of receiving data indicating a condition of an electric grid; based on the condition of the electric grid, identifying a demand for a grid service for the electric grid; accessing a database of grid assets, the database including, for each grid asset of a plurality of grid assets: an identifier for the grid asset; and operating parameters for the grid asset; selecting, from the plurality of grid assets and based on the operating parameters for the grid assets, a grid asset for performing the grid service; transmitting, to the grid asset, an instruction to perform the grid service; monitoring a status of the grid asset performing the grid service; and determining a value of the grid service performed by the grid asset.

These and other embodiments can include the following features, alone or in any combination. In some implementations, the data indicating the condition of the electric grid includes at least one of a group consisting of: voltage data indicating a measured voltage of the electric grid; frequency data indicating a measured frequency of the electric grid; and load data indicating an electrical load on the electric grid.

In some implementations, the database of grid assets includes recorded status information for the plurality of grid assets, the method including selecting the grid asset based on the recorded status information for the grid asset.

In some implementations, the recorded status information for the grid asset includes at least one of a group consisting of: an electrical load drawn by the grid asset from the electric grid; an electrical power provided by the grid asset to the electric grid; an on/off status of the grid asset; a power setting of the grid asset; a standby status of the grid asset; and a status of a connection of the grid asset to the electric grid.

In some implementations, the instruction to perform the grid service includes at least one of a group consisting of: an instruction to connect to the electric grid; an instruction to disconnect from the electric grid; an instruction to power off; an instruction to power on; and an instruction to change a power setting of the grid asset.

In some implementations, identifying the demand for the grid service includes at least one of a group consisting of: identifying a type of grid service to be performed; identifying a location for the grid service to be performed; identifying a time for the grid service to be performed; and identifying a duration for the grid service to be performed.

In some implementations, the value for the grid service includes at least one of a group consisting of: a value of currency per time increment; a total value of currency for performance of the grid service; an energy credit per time increment; a total energy credit for performance of the grid service; and a time-varying value over a duration of performance of the grid service.

In some implementations, the operating parameters for the grid asset include at least one of a group consisting of: a power rating of the grid asset; a load capacity of the grid asset; a voltage rating of the grid asset; a voltage rating of the connection point; a current rating of the grid asset; and a response time of the grid asset.

In some implementations, the grid service includes at least one of a group consisting of: electrical energy storage; load shifting; fast balancing; peak shaving; frequency regulation; frequency response; voltage regulation; reactive power injection; reactive power absorption;

In some implementations, the grid asset includes at least one of a group consisting of: a distributed energy resource; an inverter-connected resource; an electrical load; an electrical power supply; an electric vehicle; and an energy storage resource.

Other embodiments of this and other aspects include corresponding systems, apparatus, and computer programs, configured to perform the actions of the methods, encoded on computer storage devices. A system of one or more computers or other processing devices can be so configured by virtue of software, firmware, hardware, or a combination of them installed on the system that in operation cause the system to perform the actions. One or more computer programs can be so configured by virtue of having instructions that, when executed by data processing apparatus, cause the apparatus to perform the actions.

The described systems, methods, and techniques may be implemented in digital electronic circuitry, computer hardware, firmware, software, or in combinations of these elements. Apparatus implementing these techniques may include appropriate input and output devices, a computer processor, and a computer program product tangibly embodied in a machine-readable storage device for execution by a programmable processor. A process implementing these techniques may be performed by a programmable processor executing a program of instructions to perform desired functions by operating on input data and generating appropriate output. The techniques may be implemented in one or more computer programs that are executable on a programmable system including at least one programmable processor coupled to receive data and instructions from, and to transmit data and instructions to, a data storage system, at least one input device, and at least one output device. Each computer program may be implemented in a high-level procedural or object-oriented programming language, or in assembly or machine language if desired; and in any case, the language may be a compiled or interpreted language. Suitable processors include, by way of example, both general and special purpose microprocessors. Generally, a processor will receive instructions and data from a read-only memory and/or a random access memory. Storage devices suitable for tangibly embodying computer program instructions and data include all forms of non-volatile memory, including by way of example semiconductor memory devices, such as Erasable Programmable Read-Only Memory (EPROM), Electrically Erasable Programmable Read-Only Memory (EEPROM), and flash memory devices; magnetic disks such as internal hard disks and removable disks; magneto-optical disks; and Compact Disc Read-Only Memory (CD-ROM). Any of the foregoing may be supplemented by, or incorporated in, specially-designed ASICs (application-specific integrated circuits).

It will be understood that various modifications may be made. For example, other useful implementations could be achieved if steps of the disclosed techniques were performed in a different order and/or if components in the disclosed systems were combined in a different manner and/or replaced or supplemented by other components. Accordingly, other implementations are within the scope of the disclosure.

Functional operations described in this specification may be implemented in digital electronic circuitry, or in computer software, firmware, or hardware, including the structures disclosed in this specification and their structural equivalents, or in combinations of one or more of them. The techniques disclosed may be implemented as one or more computer program products, i.e., one or more modules of computer program instructions encoded on a computer-readable medium for execution by, or to control the operation of, data processing apparatus. The computer readable-medium may be a machine-readable storage device, a machine-readable storage substrate, a memory device, a composition of matter affecting a machine-readable propagated signal, or a combination of one or more of them. The computer-readable medium may be a non-transitory computer-readable medium. The term “data processing apparatus” encompasses all apparatus, devices, and machines for processing data, including by way of example a programmable processor, a computer, or multiple processors or computers. The apparatus may include, in addition to hardware, code that creates an execution environment for the computer program in question, e.g., code that constitutes processor firmware, a protocol stack, a database management system, an operating system, or a combination of one or more of them. A propagated signal is an artificially generated signal, e.g., a machine-generated electrical, optical, or electromagnetic signal that is generated to encode information for transmission to suitable receiver apparatus.

A computer program (also known as a program, software, software application, script, or code) may be written in any form of programming language, including compiled or interpreted languages, and it may be deployed in any form, including as a standalone program or as a module, component, subroutine, or other unit suitable for use in a computing environment. A computer program does not necessarily correspond to a file in a file system. A program may be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program may be deployed to be executed on one computer or on multiple computers that are located at one site or distributed across multiple sites and interconnected by a communication network.

The processes and logic flows described in this specification may be performed by one or more programmable processors executing one or more computer programs to perform functions by operating on input data and generating output. The processes and logic flows may also be performed by, and apparatus may also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Moreover, a computer may be embedded in another device, e.g., a tablet computer, a mobile telephone, a personal digital assistant (PDA), a mobile audio player, a Global Positioning System (GPS) receiver, to name just a few. Computer readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The processor and the memory may be supplemented by, or incorporated in, special purpose logic circuitry.

To provide for interaction with a user, the techniques disclosed may be implemented on a computer having a display device, e.g., a CRT (cathode ray tube) or LCD (liquid crystal display) monitor, for displaying information to the user and a keyboard and a pointing device, e.g., a mouse or a trackball, by which the user may provide input to the computer. Other kinds of devices may be used to provide for interaction with a user as well; for example, feedback provided to the user may be any form of sensory feedback, e.g., visual feedback, auditory feedback, or tactile feedback; and input from the user may be received in any form, including acoustic, speech, or tactile input.

Implementations may include a computing system that includes a back end component, e.g., as a data server, or that includes a middleware component, e.g., an application server, or that includes a front end component, e.g., a client computer having a graphical user interface or a Web browser through which a user may interact with an implementation of the techniques disclosed, or any combination of one or more such back end, middleware, or front end components. The components of the system may be interconnected by any form or medium of digital data communication, e.g., a communication network. Examples of communication networks include a local area network (“LAN”) and a wide area network (“WAN”), e.g., the Internet.

The computing system may include clients and servers. A client and server are generally remote from each other and typically interact through a communication network. The relationship of client and server arises by virtue of computer programs running on the respective computers and having a client-server relationship to each other.

While this specification contains many specifics, these should not be construed as limitations, but rather as descriptions of features specific to particular implementations. Certain features that are described in this specification in the context of separate implementations may also be implemented in combination in a single implementation. Conversely, various features that are described in the context of a single implementation may also be implemented in multiple implementations separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems may generally be integrated together in a single software product or packaged into multiple software products.

Thus, particular implementations have been described. Other implementations are within the scope of the following claims. For example, the actions recited in the claims may be performed in a different order and still achieve desirable results.

What is claimed is:

1. A computer-implemented method comprising:
detecting a connection of a grid asset to an electric grid at a connection point;
receiving, from the grid asset, a communication indicating operating parameters for the grid asset;
adding, to a database of grid assets, an identifier for the grid asset and the operating parameters for the grid asset; and
simulating conditions of the electric grid based on data corresponding to a plurality of grid assets, the data being stored in the database and comprising the operating parameters for the grid asset.

2. The method of claim 1, comprising
transmitting, to the grid asset, a request for operating parameters for the grid asset; and
receiving, from the grid asset, the communication indicating the operating parameters for the grid asset in response to transmitting the request.

3. The method of claim 1, wherein receiving the communication indicating the operating parameters for the grid asset comprises receiving the communication from the grid asset in response to the grid asset connecting to the electric grid.

4. The method of claim 1, wherein the operating parameters for the grid asset comprise at least one of a group consisting of:
a power rating of the grid asset;
a load capacity of the grid asset;
a voltage rating of the grid asset;
a voltage rating of the connection point;
a current rating of the grid asset; and
a response time of the grid asset.

5. The method of claim 1, comprising:
after adding the identifier for the grid asset to the database of grid assets, transmitting, to the grid asset, a request for status information for the grid asset;
receiving, from the grid asset, a response to the request, the response including the status information for the grid asset; and
determining, based on the status information for the grid asset, an availability of the grid asset to perform a grid service.

6. The method of claim 5, comprising recording, in a distributed database, the availability of the grid asset to perform the grid service.

7. The method of claim 5, wherein the status information for the grid asset comprises at least one of a group consisting of:
an electrical load drawn by the grid asset from the electric grid;
an electrical power provided by the grid asset to the electric grid;
an on/off status of the grid asset;
a power setting of the grid asset;
a standby status of the grid asset; and
a status of the connection of the grid asset to the electric grid.

8. The method of claim 5, comprising:
determining that the grid asset is not available to perform the grid service; and
in response to determining that the grid asset is not available to perform the grid service, selecting another grid asset to provide the grid service.

9. A computer-implemented method comprising:
simulating conditions of an electric grid to obtain simulation results, including simulating an electric grid event;
determining, based on the simulation results, that the simulated electric grid event is associated with a demand for a grid service for the electric grid;
accessing a database of grid assets electrically connected to the electric grid, the database including for each grid asset of a plurality of grid assets:
an identifier for the grid asset; and
operating parameters for the grid asset;
selecting, from the plurality of grid assets and based on the operating parameters for the grid assets, a grid asset for performing the grid service; and
estimating a value of the grid asset performing the grid service.

10. The method of claim 9, wherein estimating the value of the grid asset performing the grid service comprises:
simulating conditions of the electric grid, including simulating the electric grid event with the grid service performed, to obtain second simulation results; and
comparing the second simulation results to the simulation results.

11. The method of claim 9, comprising selecting the grid asset based on at least one of a group consisting of:
a status of the grid asset;
a location of the grid asset relative to the electric grid; and
a location of the grid asset relative to a location of the electric grid event.

12. The method of claim 9, comprising:
obtaining data indicating a status of a grid asset connected to an electric grid;
determining, based on the status of the grid asset, that the grid asset is performing the grid service;
obtaining energy market data indicating a market value of energy provided by the electric grid; and
determining a value for the grid service performed by the grid asset based on (a) the estimated value of the grid service performed by the grid asset and (b) the energy market data.

13. The method of claim 9, wherein the value for the grid service comprises at least one of a group consisting of:
a value of currency per time increment that the grid service is performed;
a total value of currency for performance of the grid service;
an energy credit per time increment that the grid service is performed;
a total energy credit for performance of the grid service; and
a time-varying value over a duration of performance of the grid service.

14. The method of claim 9, wherein the operating parameters for the grid asset comprise at least one of a group consisting of:
a power rating of the grid asset;
a load capacity of the grid asset;
a voltage rating of the grid asset;
a voltage rating of a connection point of the grid asset to the electric grid;
a current rating of the grid asset; and
a response time of the grid asset.

15. The method of claim 9, wherein the grid service comprises at least one of a group consisting of:
electrical energy storage;
load shifting;
fast balancing;
peak shaving;
frequency regulation;
frequency response;
voltage regulation;
reactive power injection;
reactive power absorption;
active power injection;
emergency energy supply; and
inertial service.

16. A computer-implemented method comprising:
obtaining data indicating a status of a grid asset connected to an electric grid;
determining, based on the status of the grid asset, that the grid asset is performing a grid service;
obtaining an estimated value of the grid service performed by the grid asset;
obtaining energy market data indicating a market value of energy provided by the electric grid; and
determining a value for the grid service performed by the grid asset based on (a) the estimated value of the grid service performed by the grid asset and (b) the energy market data.

17. The method of claim 16, wherein obtaining the data indicating the status of the grid asset comprises obtaining, from an electric meter associated with the grid asset, measurement data representing a measurement taken for the grid asset.

18. The method of claim 17, wherein determining that the grid asset is performing the grid service comprises determining, using the measurement data, that the grid asset is providing electrical power to the electric grid or is receiving electrical power from the electric grid.

19. The method of claim 16, wherein determining that the grid asset is performing the grid service comprises:
determining that an electric grid event occurred at a first time, the electric grid event being associated with a demand for the grid service;
identifying a set of grid assets that are relevant to the electric grid event, the set of grid assets including the grid asset;
determining, based on information recorded in a distributed database, that the grid asset was available to perform the grid service at or before the first time; and
determining that the status of the grid asset matches an expected status of the grid asset when performing the grid service.

20. The method of claim 19, wherein the energy market data corresponds to a type of the electric grid event that occurred and the type of grid service provided.
